(19) United States
(12) Patent Application Publication
(10) Pub. No.: US 2026/0360668 A1
(43) Pub. Date: Nov. 12, 2026

(54) SWITCHING POWER SUPPLY TOPOLOGIES

(71) Applicant: AES Global Holdings Pte. Ltd., Singapore (SG)

(72) Inventors: Maneesh Kumar Singh, Fort Collins, CO (US); Michael Dean Armstrong, Loveland, CO (US); John Dorrenbacher, Fort Collins, CO (US); Joshua B. Pankratz, Fort Collins, CO (US); Tony Hanlin Shi, Redwood City, CA (US); Wei Liang, San Jose, CA (US)

(73) Assignee: AES Global Holdings Pte. Ltd., Singapore (SG)

(21) Appl. No.: 19/669,095

(22) Filed: May 6, 2026

Related U.S. Application Data
(60) Provisional application No. 63/826,291, filed on Jun. 18, 2025.
(60) Provisional application No. 63/822,714, filed on Jun. 12, 2025.
(60) Provisional application No. 63/801,755, filed on May 7, 2025.

(51) Int. Cl. H01J 37/32

(52) U.S. Cl. CPC H01J 37/32128; H01J 37/32183; H01J 2237/327

(57) ABSTRACT

Methods, apparatus, and systems for producing a waveform are disclosed. An apparatus comprises a first node, a switch section configured to produce a voltage waveform at the first node while the first node is coupled to a load, the voltage waveform comprising a rising edge that reaches a peak and a falling edge that falls from the peak. A controller is configured to operate the switch section so the switch section neither provides current to first node nor receives current from the first node at a time between the rising edge and the falling edge.

### CLAIM OF PRIORITY UNDER 35 U.S.C. §119

The present Application for Patent claims priority to the following three U.S. provisional patent applications: U.S. Provisional Application No. 63/801,755 entitled “POWER SUPPLY TOPOLOGIES AND METHODS OF OPERATION” filed May 7, 2025; U.S. Provisional Application No. 63/822,714 entitled “POWER SUPPLY TOPOLOGIES AND METHODS OF OPERATION FOR PLASMA PROCESSING“ filed Jun. 12, 2025; and U.S. Provisional Application No. 63/826,291 entitled SWITCHING POWER SUPPLY TOPOLOGIES filed Jun. 18, 2025 and assigned to the assignee hereof and hereby expressly incorporated by reference herein.

### BACKGROUND

### Field

The present invention relates generally to power supplies, and more specifically to power supplies for plasma processing.

### Background

Many types of semiconductor devices are fabricated using plasma-based etching techniques. Prior techniques to achieve a narrow ion energy distribution during plasma processing are expensive, inefficient, and difficult to control.

Further limitations and disadvantages will become apparent to one of skill in the art through comparison of prior techniques with the present disclosure.

### BRIEF DESCRIPTION OF THE DRAWINGS

FIG. 1A is a block diagram depicting an example processing system;

FIG. 1B is a graph illustrating a voltage waveform;

FIG. 2A is a block diagram depicting aspects of an example bias supply;

FIG. 2B is a block diagram depicting additional aspects of the example bias supply shown in FIG. 2A;

FIG. 2C is a block diagram depicting yet additional aspects of the example bias supply shown in FIGS. 2A and 2B;

FIG. 3 depicts an example topology;

FIG. 4 depicts another example topology;

FIG. 5 is a schematic view of an example bias supply;

FIG. 6A is a timing and switching diagram depicting a first time window of operation;

FIG. 6B is a timing and switching diagram depicting a second time window of operation;

FIG. 6C is a timing and switching diagram depicting a third time window of operation;

FIG. 6D is a timing and switching diagram depicting a fourth time window of operation;

FIG. 6E is a timing and switching diagram depicting a fifth time window of operation;

FIG. 7 is a schematic view of another topology;

FIG. 8 is a schematic view of an example bias supply;

FIG. 9 is a timing diagram associated with the topology depicted in FIG. 7 and the bias supply shown in FIG. 8;

FIG. 10 is a schematic view of another bias supply;

FIG. 11 is an example timing diagram for the operation of the bias supply shown in FIG. 10;

FIG. 12 depicts yet another example bias supply;

FIG. 13 is a timing diagram depicting operation for the bias supply shown in FIG. 12;

FIG. 14 depicts another example bias supply;

FIG. 15 is a timing diagram depicting operation for the bias supply shown in FIG. 14;

FIG. 16 depicts another example topology;

FIG. 17 is a timing diagram for the topology depicted in FIG. 16;

FIG. 18 is a schematic of an example topology;

FIG. 19 is a timing diagram for the topology depicted in FIG. 18;

FIG. 20 is a schematic of another example topology;

FIG. 21 is a timing diagram that may be used with the topology shown in FIG. 20;

FIG. 22 is a schematic diagram for another topology;

FIG. 23 is a timing diagram for the topology depicted in FIG. 22;

FIG. 24 is a schematic presentation of a bias supply;

FIG. 25 is a schematic presentation of another bias supply;

FIG. 26 is a timing diagram that may be used with the bias supplies depicted FIGS. 24 and 25;

FIG. 27 is a graph depicting examples of waveforms that may be produced with topologies and bias supplies disclosed herein;

FIG. 28 is a schematic diagram of yet another bias supply;

FIG. 29 is a timing diagram for the bias supply depicted in FIG. 28;

FIG. 30 is an example of waveforms that may be produced with the bias supply;

FIG. 31 is a schematic depiction of an example load;

FIG. 32 is a block diagram depicting an example of control-related components.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

As used herein, the term “approximately” (or “about”) is intended to account for variations that can occur due to measurement precision, manufacturing tolerances, and the like. Unless otherwise indicated, “approximately” means within a reasonable range of the stated value as understood by a person of ordinary skill in the art, which may be within ±10%, ±5%, ±2%, or ±1% of the stated value, depending on the context. In some embodiments, “approximately” may mean essentially the same as the stated value such that the difference is insignificant for the intended purpose, or values that achieve substantially the same result as the stated value.

Preliminary note: the flowcharts and block diagrams in the following Figures illustrate the architecture, functionality, and operation of possible implementations of systems, methods and computer program products according to various embodiments. In this regard, some blocks in these flowcharts or block diagrams may represent a module, segment, or portion of code, which comprises one or more executable instructions for implementing the specified logical function(s). The instructions may be executable by a processor or may be used to program a field programmable gate array. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

For the purposes of this disclosure, source generators, source supplies, or excitation supplies are those whose energy is primarily directed to generating and sustaining the plasma, while “bias supplies” are those whose energy is primarily directed to generating a surface potential for attracting ions and electrons from the plasma. As used herein, “coupled” means directly or indirectly coupled unless otherwise specified, and “connected” means directly connected.

It should be recognized that control, metrology, sensing, gate drive, and sensing aspects disclosed herein may be used in connection with any of the depicted bias supplies and topologies disclosed herein regardless of whether the depicted bias supplies and topologies are characterized as embodiments or examples.

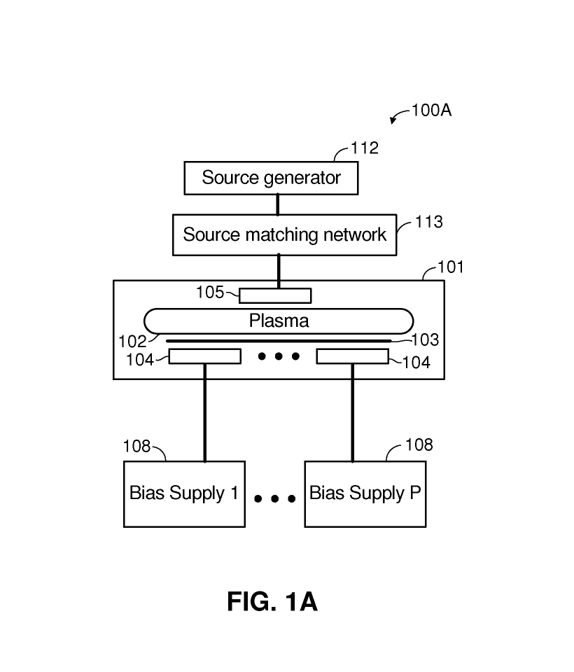

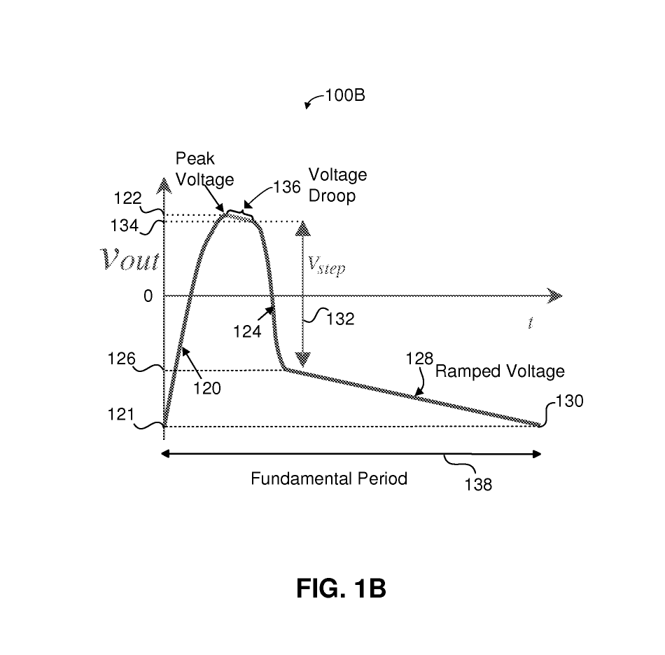

Referring first to FIG. 1A, shown is an example plasma processing environment (e.g., deposition or etch system) 100A in which bias supplies 108 may be utilized. In some examples, bias supply 108 may be referred to as a bias power supply or a bias waveform generator. Plasma processing environment 100A may include various devices or components coupled directly and indirectly to a plasma processing chamber 101, within which a volume containing a plasma 102 and workpiece 103 (e.g., a wafer or substrate) and electrodes 104 (which may be embedded in a substrate support) are contained. In some examples, environment 100A may include vacuum handling and gas delivery equipment (not shown), one or more bias supplies 108, one or more source generators 112, and one or more source matching networks 113. In some examples, source generator 112 may be referred to as a source power supply.

In some examples, power from a single source generator 112 may be connected to one or multiple source electrodes 105. The source generator 112 may be a higher frequency radio frequency (RF) generator (e.g., approximately 13.56 MHz to approximately 120 MHz). The electrode 105 may be implemented with an inductively coupled plasma (ICP) source, a dual capacitively-coupled plasma source (CCP) having a secondary top electrode biased at another RF frequency, a helicon plasma source, a microwave plasma source, a magnetron, or some other independently operated source of plasma energy. In some examples, the bias supply 108 can produce a periodic voltage waveform that can be hundreds of kilohertz (e.g., approximately 400 kHz), and the frequency of the source generator 112 may be in the megahertz (e.g., approximately 13.56 MHz).

In variations of the system depicted in FIG. 1A, the source generator 112 and source matching network 113 may be replaced by, or augmented with, a remote plasma source. In some examples, the source generator 112, source matching network 113, and plasma chamber 101 may be coupled together by one or more cables, may be directly coupled to one another (e.g., without cables), or may be coupled by a combination thereof. In some examples, source generator 112 and matching network 113 may be within a single enclosure or housing structure. And other variations of the system may include only a single bias supply 108. It should be recognized that many other variations of the plasma processing environment depicted in FIG. 1 may be utilized. As examples without limitation, U.S. Patent No. 10,707,055, issued Jul. 7, 2020 and U.S. Patent No. 10,811,227, issued Oct. 20, 2020, both of which are incorporated by reference in their entirety, disclose various types of system designs.

It should be recognized that, while the following disclosure may be used for plasma-based wafer processing, implementations can include any substrate processing within a plasma chamber. In some instances, objects other than a substrate can be processed using the systems, methods, and apparatus herein disclosed. In other words, this disclosure applies to plasma processing of any object within a sub-atmospheric plasma processing chamber to affect a surface change, subsurface change, deposition or removal by physical or chemical means.

Referring to FIG. 1B, shown is an example cycle of a voltage waveform 100B that may be produced by a bias supply such as, for example, bias supply 108 and the bias supplies disclosed further herein. In some examples, the waveform 100B may be periodic and comprise pulses and a portion between the pulses. The pulses may comprise a rising edge 120 that begins at first negative voltage 121 and reaches a peak voltage 122. The pulses may comprise a falling edge 124 that follows the peak voltage 122. As shown, the falling edge 124 may end at a second negative voltage 126. A ramped voltage 128 may follow the falling edge 124. The ramped voltage 128 may begin at the second negative voltage 126, end at a third negative voltage 130, and have a negative voltage slope. The waveform 100B may comprise voltage step (Vstep) 132 that is a difference between the peak voltage 122 and the second negative voltage 126.

The peak voltage 122 may be a positive voltage, but in some implementations, this is not required. In variations where the peak voltage 122 is positive, the voltage step 132 may change from a positive voltage to a negative voltage. As shown, the ramped voltage 128 may have a negative slope that begins at the second negative voltage 126 and becomes an increasingly negative voltage over time until a next rising edge of another pulse (not shown) at third negative voltage 130. The depicted cycle of waveform 100B may repeat at a frequency of 400 kHz or another frequency. Aspects of the waveform 100B may change over time. For example, voltage step 132 may be changed to change a distribution of ion energies in the plasma processing chamber 101. The ramped voltage 128 may be changed to change a level of ion current compensation. A length of time the peak voltage 122 is provided may be changed to change a duty cycle of the waveform 100B. The third negative voltage 130 may be the same as the first negative voltage 121 over several cycles. The third negative voltage 130 may be different than the first negative voltage 121, for example, when one or more aspects of the waveform 100B are changed.

Waveform 100B can be asymmetric over a fundamental period 138 relative to a reference voltage, such as, for example, ground. In some examples, waveform 100B can be referred to as a non-sinusoidal waveform, and bias supply 108 may be a non-sinusoidal bias generator or an asymmetric waveform generator 108 to provide waveform 100B. As shown in FIG. 1B, the ramped voltage 128 of the waveform 100B may last substantially longer than the pulsed portion, but this is not required. In addition, the rising edge 120 and falling edge 124 of the pulses may be nearly instantaneous, or in other examples may increase and decrease, respectively, with a defined ramp rate.

In some implementations, it may be desirable to have control over a length of time that the voltage waveform 100B resides at, or near, the peak voltage 122 relative to the fundamental period 138 of the voltage waveform. This length of time is referred to herein as the duty cycle of the voltage waveform 100B. An aspect of at least several examples disclosed in the present disclosure is control over the duty cycle of the waveform 100B to control the duration of a pulse portion of the voltage waveform. An aspect of at least some examples disclosed in the present disclosure is control over the duty cycle of the waveform 100B to control the duration of a positive portion of the voltage waveform 100B. In addition, as shown in FIG. 1B, some examples may produce a negative slope between the peak voltage 122 and the beginning 134 of the voltage step 132 and the negative slope between the peak voltage 122 and beginning 134 of the voltage step 132 may be referred to as a voltage droop 136. In some implementations, it may be desirable to reduce the voltage droop 136. For example, it may be desirable to reduce the duration of the voltage droop 136 and/or a voltage change that occurs between the peak voltage 122 and the beginning 134 of the falling edge 124. In some of the example bias supplies disclosed herein, the voltage droop 136 may be reduced or eliminated.

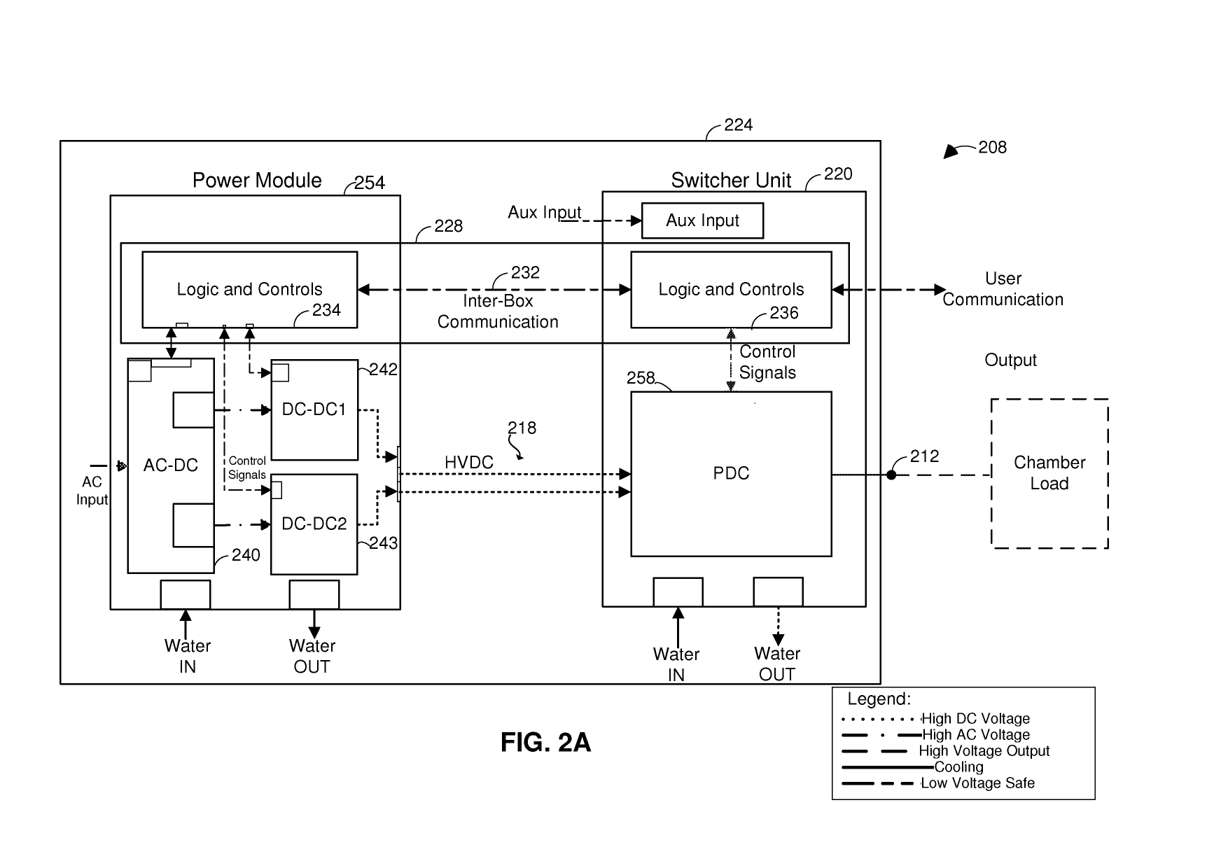

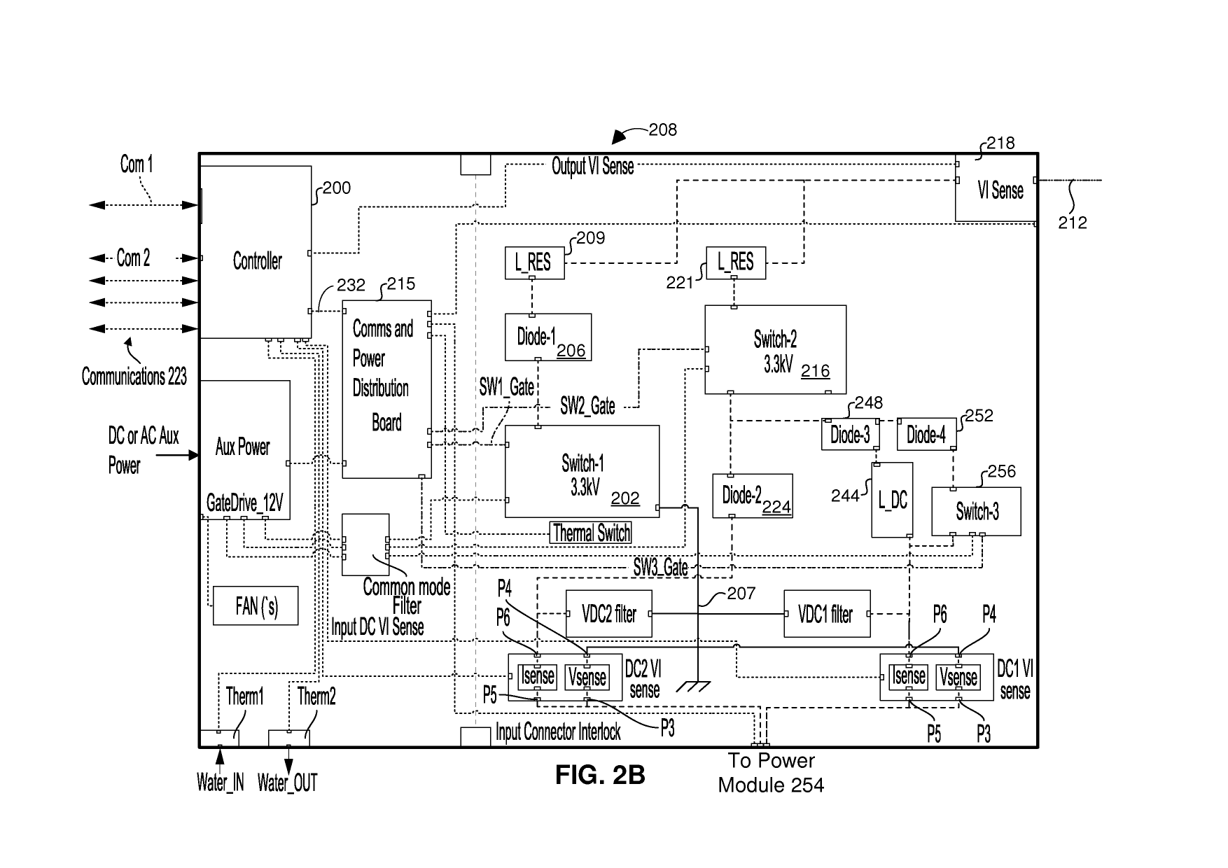

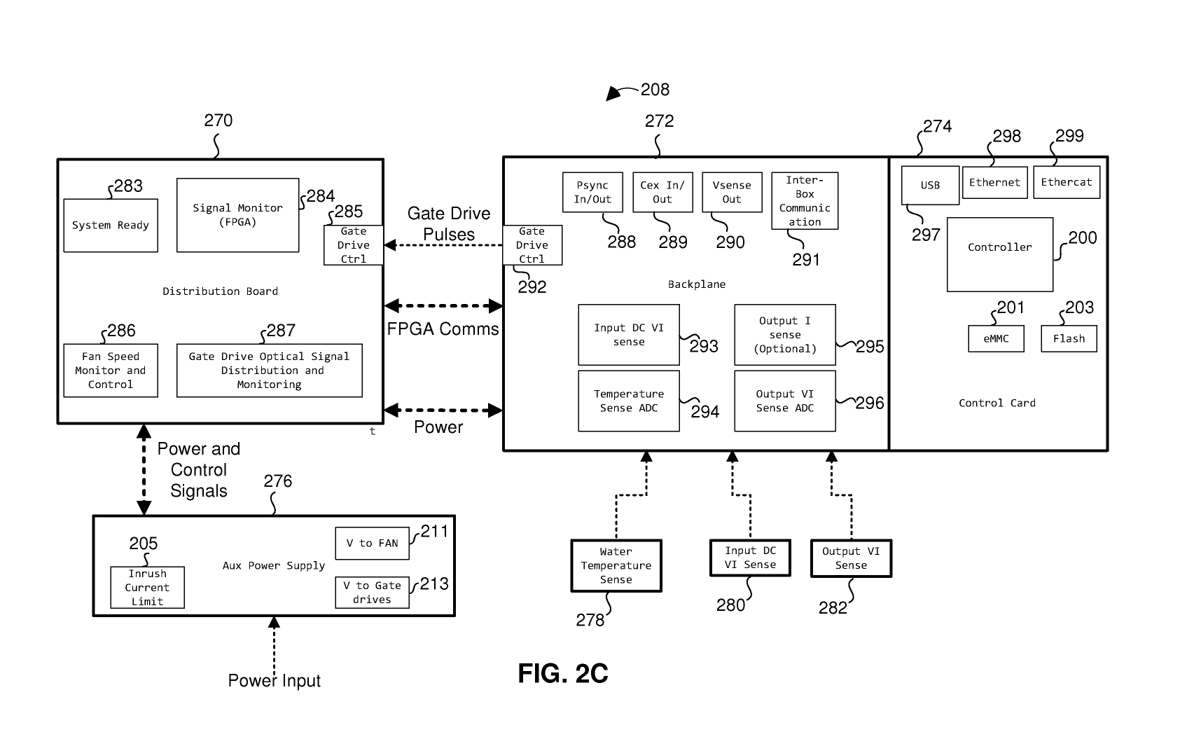

Referring to FIG. 2A, shown is a block diagram depicting a top level system view of an example bias supply 208. As shown, the bias supply 208 may comprise a power module 254 and a switcher unit 220. The power module 254 and the switcher unit 220 may be implemented to reside in a common housing 224 of the bias supply 208. Alternatively, the power module 254 and the switcher unit 220 may reside in separate housings. The bias supply 208 may comprise control logic 228. The control logic 228 may reside in part within the power module 254 and in part within the switcher unit 220. A communication link 232 may couple a first portion 234 and a second portion 236 of the control logic 228.

The power module 254 may comprise an AC-DC module 240, a first DC module 242, and a second DC module 243. The switcher unit 220 may comprise a power distribution center 258, and the power distribution center 258 may be coupled to a load such as the plasma processing chamber 101. As described further herein, the power distribution center 258 may function to produce the waveform 100B without the voltage droop depicted in FIG. 1B. For example, the power distribution center 258 may produce the waveform 100B so that the voltage of the waveform 100B between the rising edge 120 and the falling edge 124 remains approximately at the peak voltage 122 without substantial voltage droop 136. The power distribution center 258 may operate so that neither current is provided to a load (e.g., the plasma processing chamber 101) nor received from the load at a time between the rising edge 120 and the falling edge 124. As discussed further herein, the power distribution center 258 may comprise a switch section that is controlled so that neither current is provided to a load (e.g., the plasma processing chamber 101) nor received from the load at a time between the rising edge 120 and the falling edge 124.

Referring to FIG. 2B, shown is a block diagram depicting a schematic level depiction of the example bias supply 208. As shown, the bias supply 208 may comprise a first switch 202 that is coupled between a first diode 206 and a ground terminal 207. The first diode 206 may be coupled between the first switch 202 and the first inductor 209. The first inductor 209 may be coupled between the first diode 206 and node 212. Node 212 may be an output node 212. A second switch 216 may be coupled between a second inductor 221 and a second diode 224. The second inductor 221 may be coupled between the second switch 216 and the node 212. The second diode 224 may be coupled between the second switch 216 and a positive power terminal. A third inductor 244 may be coupled between the third diode 248 and another positive power terminal. A third switch 256 may be coupled between the third diode 248 and the third inductor 244.

The bias supply 208 may comprise a sensor 218. The sensor 218 may be a voltage sensor. The sensor 218 may comprise two sensors. The sensor 218 may comprise a voltage-current (“VI”) sensor. The sensor 218 may provide feedback to a controller 200. The controller 200 may comprise control logic 228 to produce gate drive signals. The controller 200 may reside in the switcher unit 220. The controller 200 may comprise the second portion 236 of the control logic 228. A distribution board 215 may comprise the first portion 234 of the control logic 228. The controller 200 may comprise logic for generating gate drive signals. The logic for generating the gate drive signals may comprise logic for controlling the gate drive signals based upon operating settings received via Com1 link. The logic for generating the gate drive signals may comprise logic for controlling the gate drive signals based upon operating settings received via the Com1 link. The logic for generating the gate drive signals may comprise logic for controlling the gate drive signals, the first DC module 242, and the second DC module 243 based upon operating settings received via the Com1 link and feedback from the sensor 218. Communication link 223 may comprise a plurality of communication links 223. Communication link 223 may enable controller 200 to communicate with source generator 112. Communication link 223 may enable controller 200 to communicate with the power module 254.

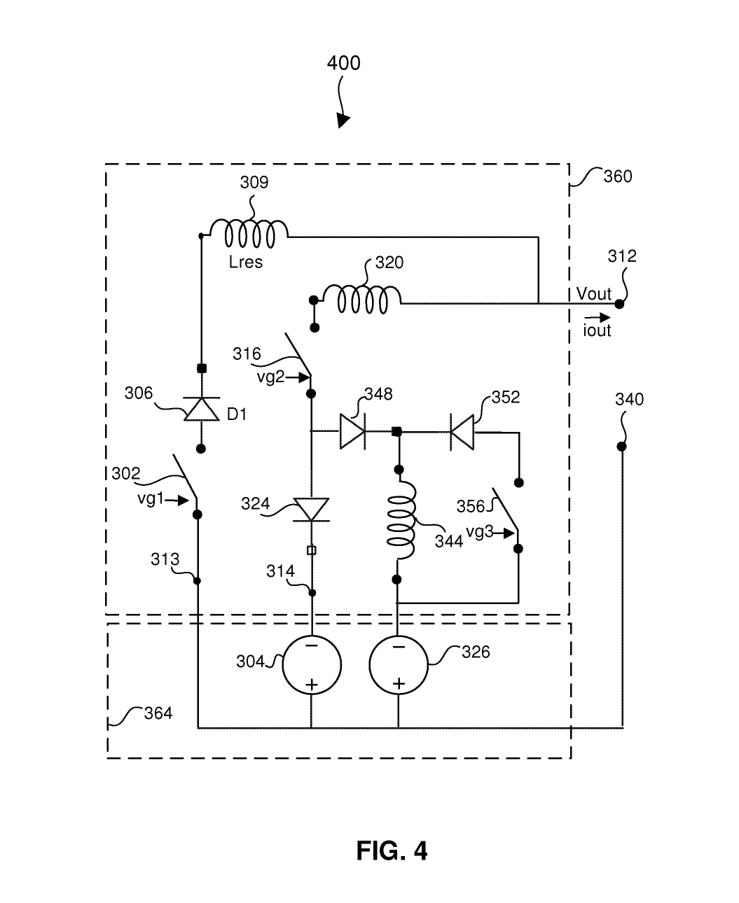

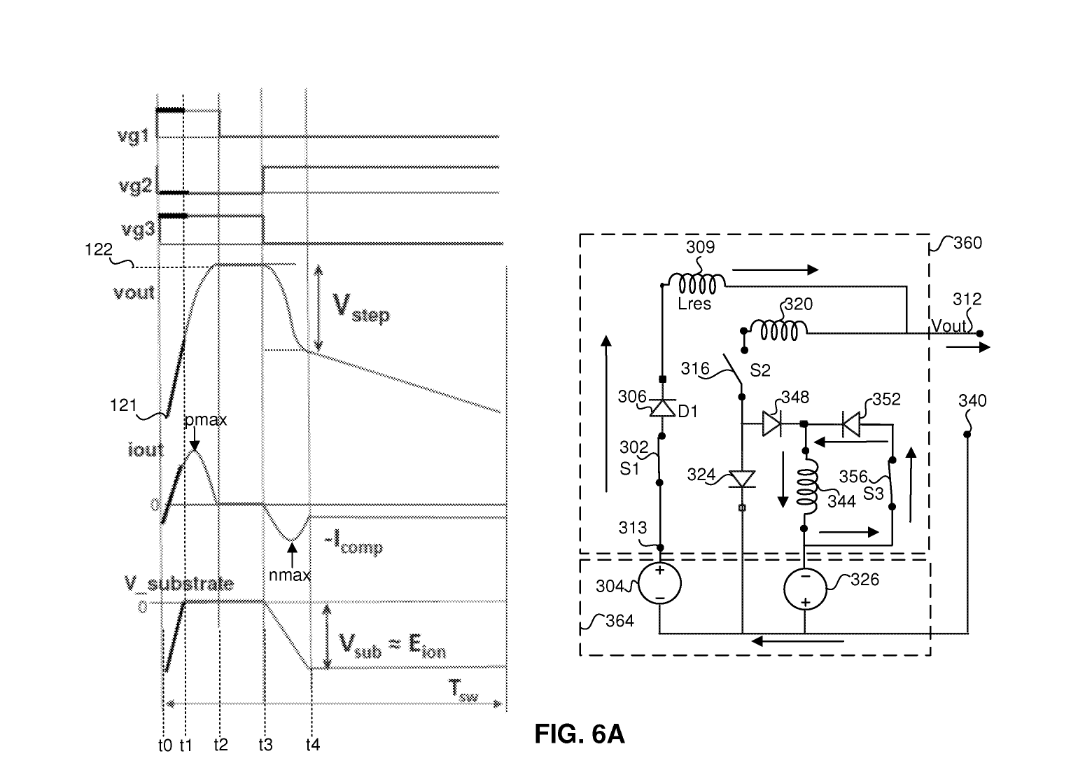

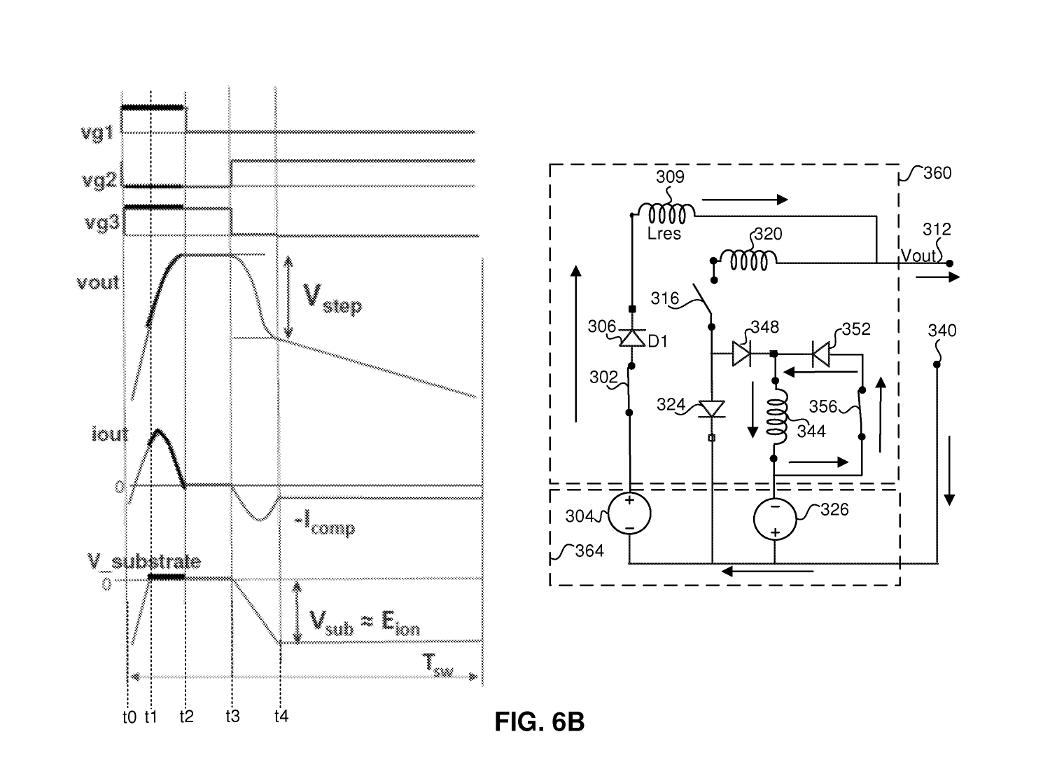

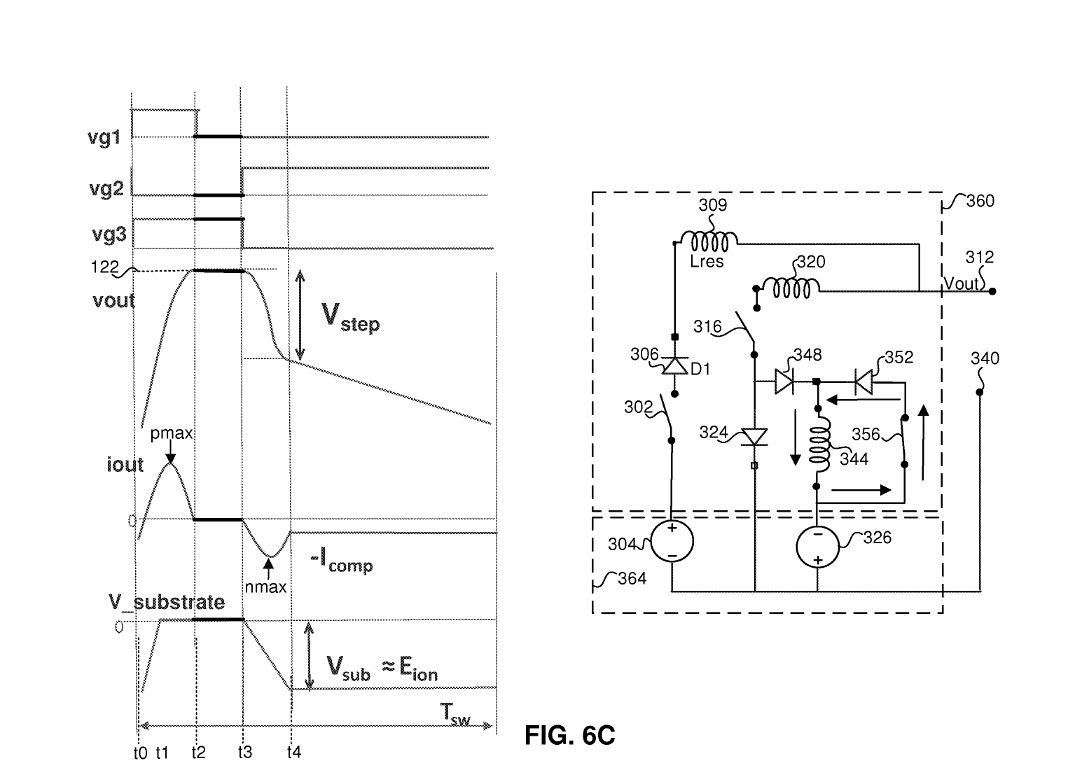

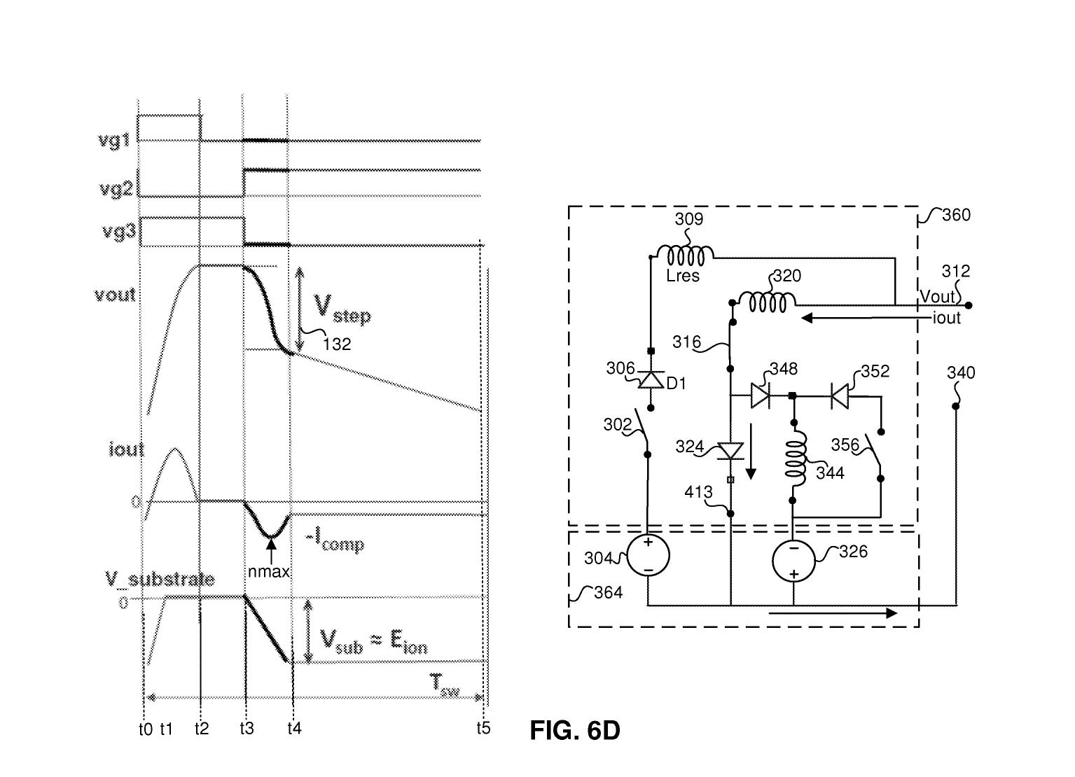

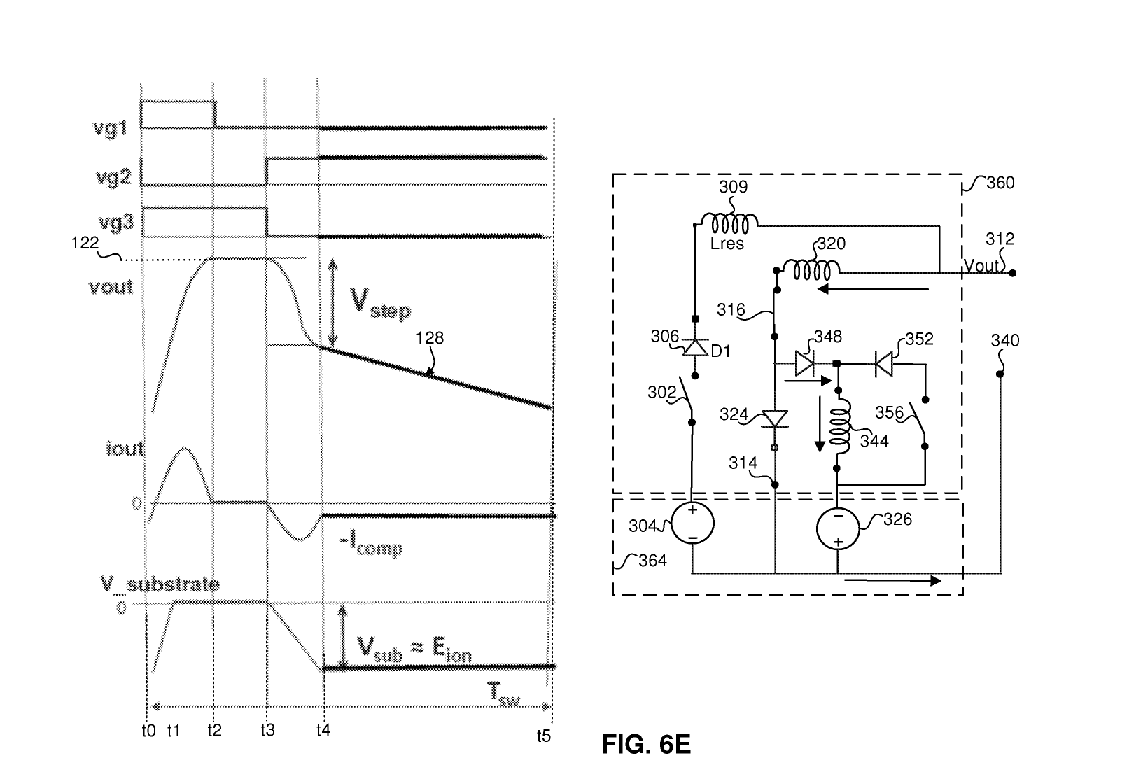

The distribution board 215 may receive gate drive signals from the controller 200. The distribution board 215 may convert the gate drive signals to optical gate drive signals and send gate drive signals to each of the switches 202, 216, 256. Each of the switches 202, 216, 256 may be arranged in a corresponding switch module configured to convert the optical gate drive signals to electrical gate drive signals. The electrical gate drive signals may be at a voltage level to close the switches. As discussed herein, the switches 202, 216, 256 may be field effect transistors, and each of the switches 202, 216, 256 may comprise multiple switches that are simultaneously switched by the switch module. The topology for the arrangement of switches, inductors, and diodes that is shown in FIG. 2B is generally the same as the topology depicted in FIG. 4, which may utilize the timing diagrams depicted in FIGS. 6A - 6E.

Referring next to FIG. 2C, shown is a block diagram depicting functional logic of the example bias supply 208. As shown, the bias supply 208 may comprise a distribution board 270, a backplane 272, a control card 274, an auxiliary power supply 276, water and temperature sensing 278, input sensors 280, and output sensors 282. As shown, the distribution board 270 may comprise a system ready indicator 283, signal monitor 284, gate drive receiver 285, fan controller 286, and gate drive distributor 287. The auxiliary power supply 276 may comprise an inrush current limiter 205, a fan voltage regulator 211, and a gate driver voltage regulator 213. The backplane 272 may comprise a Psync In/Out module 288, a Cex In/Out module 289, a Vsense output module 290, an inter-box communication module 291, a gate drive control module 292, an input DC sensing module 293, a temperature analog to digital converter 294, an optional output current sensor 295, and output sensing analog to digital converter 296. The control card 274 may comprise a USB interface 297, ethernet interface 298, an ethercat interface 299, a controller 200, a nonvolatile memory module 201, and a flash memory module 203.

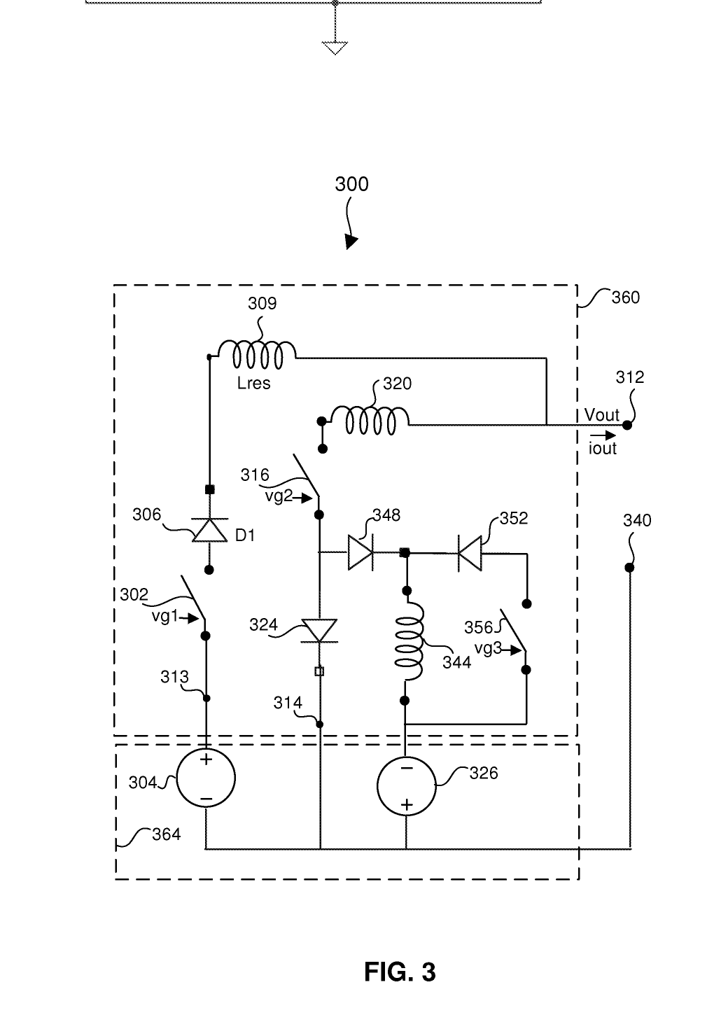

Referring to FIG. 3, shown is an example topology 300 that may be used to implement portions of the bias supply 208. The topology 300 comprises a switch section 360 that may be used to implement the switch section 260. The topology 300 also comprises a power module 364 that may be used to implement the power module 254. As shown, the topology 300 may comprise a first power supply 326 and a second power supply 304. The first power supply 326 may comprise a DC power supply and the second power supply 304 may comprise a DC power supply. As shown, the topology 300 may comprise a first switch 302 that is coupled between a positive node of the second power supply 304 and an anode of a first diode 306, and a cathode of the first diode 306 is coupled to a first node of a first inductor 309. A second node of the first inductor 309 may be coupled to node 312. Node 312 may be an output node 312. A second switch 316 may be coupled between a first node of a second inductor 320 and an anode of a second diode 324. A second node of the second inductor 320 may be coupled to the node 312. A cathode of the second diode 324 may be coupled to both, a negative terminal of the second power supply 304 and a positive terminal of the first power supply 326. A return 340 may be coupled to the cathode of the second diode 324, the negative terminal of the second power supply 304 and the positive terminal of the first power supply 326. A third inductor 344 may be coupled to both a cathode of a third diode 348 and a cathode of a fourth diode 352. A third switch 356 may be coupled between an anode of the third diode 348 and the second node of the third inductor 344. Although the second power supply 304 is depicted with a polarity that functions to source power. It should be recognized that the second power supply 304 may be a bidirectional power supply that may also sink power.

In operation, the first switch 302 may couple the first node 312 to a second node 313, and responsive to the first switch 302 being closed, the rising edge 120 of the voltage waveform 100B is produced at the first node 312 until the voltage peak 122 is reached. The second switch 316 couples a third node 314 to the first node 312, and when the second switch 316 is closed, the voltage step 132 is produced at the first node. The third switch 356 may be configured to close to circulate current in a loop during the voltage peak 122. The loop may comprise the fourth diode 352, the third inductor 344, and the third inductor 344. The third node 314 may be a same node as the return node 340. The return node 340 may be configured to couple to ground. The return node may be a chassis of a bias supply that incorporates the topology 300.

Referring to FIG. 4, shown is another topology 400 that may be used to implement portions of the bias supply 208. The topology 400 is similar to the topology 300 except the second power supply 304 is coupled between the cathode of the second diode 324. A negative terminal of the second power supply 304 may be coupled to the cathode of the second diode 324 and a positive terminal of the first power supply 326 may be coupled to the third node 314. In operation, the first switch 302 couples the first node 312 to a second node 313, and responsive to the first switch 302 being closed, the rising edge 120 of the voltage waveform 100B is produced at the first node 312 until the voltage peak 122 is reached. The second switch 316 couples the third node 314 to the first node 312, and when the second switch 316 is closed, the voltage step 132 is produced at the first node. The third switch 356 may be configured to close to circulate current in a loop during the voltage peak 122. The loop may comprise the fourth diode 352, the third inductor 344, and the third inductor 344. Although the second power supply 304 is depicted with a polarity that functions to source power, it should be recognized that the second power supply 304 may be a bidirectional power supply that may also sink power.

Each of the switches 302, 316, 356 depicted in FIGS. 3 and 4 generally represents one or more switches that may be capable of closing and opening to connect and disconnect, respectively, a current pathway. For example, a single switch depicted in FIGS. 3 and 4 may be realized by a plurality of switches arranged in series (for enhanced voltage capability), may be realized by a plurality of switches arranged in parallel (for enhanced current capability), or the single switch may be comprised of a plurality of switches arranged in a series-parallel combination (for enhanced voltage and/or current capability). In these variations, each switch that is used to realize a particular one of the switches 302, 316, and 356 may be driven by a corresponding drive signal.

In some implementations, the switches disclosed herein (including switches 302, 316, 356) may be realized by field-effect switches such as metal-oxide semiconductor field-effect transistors (MOSFETS), and in other implementations, the switches may be realized by silicon carbide metal-oxide semiconductor field-effect transistors (SiC MOSFETs) or gallium nitride metal-oxide semiconductor field-effect transistors (GaN MOSFETs). As another example, the switches may be realized by an insulated gate bipolar transistor (IGBT). It is also contemplated that the drive signals may be sent via optical lines to convey optical switching signals. And the switches may switch in response to the optical signal and/or optical signals that are generated from an initial electrical drive signal.

It should also be recognized that any of the diodes depicted herein (including diodes 306, 324, 348) may be realized by a plurality of diodes. For example, any diode may be realized by a plurality of series-connected diodes (to enhance voltage capability), may be realized by a plurality of diodes arranged in parallel (to enhance current capability), or may be comprised of a plurality of diodes arranged in a series-parallel combination (for enhanced voltage and/or current capability).

Although not shown in FIGS. 3 and 4 for clarity, as discussed further herein, the topology may be implemented as a portion of a drivetrain in a bias supply that may comprise a controller. The topology may be separated into a switch section 360 and a power module 364. Alternatively, the switch section 360 may be integrated with power components (e.g., the second power supply 304 and the first power supply 326) so that the power module 364 is not identifiable as a separated physical component from the switch section 360. As discussed further herein, the topology 300 may be implemented in a bias supply (e.g., bias supply 108) with a controller that may comprise metrology, data processing, and control logic. The controller may be coupled to the switches 302, 316, 356 to provide gate drive signals to the switches, the controller may be coupled to the first power supply 326 and the second power supply 304 by communication links to enable the controller to control the first second supply 304 and the first power supply 326. In FIGS. 3 and 4 all of the switches 302, 316, 356 are depicted in an open position.

The controller may receive signals (e.g., feedback signals) indicative of one or more power-related parameters such as, for example and without limitation, Vout and iout. The signals may comprise signals indicative of forward power, reflected power, and phase. One or more sensors may provide the signals. The one or more sensors may be coupled to the node 312. The node 312 may be an output of a bias supply (e.g., bias supply 108). As discussed further herein, the one or more sensors may be realized by, for example and without limitation, sensors that provide information indicative of voltage and/or current at the node 312. For example, and without limitation, the one or more sensors 315 may be realized by a VI sensor, a directional coupler or by separate voltage and current sensors.

The controller may control a voltage of second power supply 304 and the first power supply 326. The controller may receive input that provides, for example, one or more setpoints to the controller. The setpoints, for example, may define one or more aspects of the voltage waveform at node 312. The one or more controlled aspects may comprise the duty cycle, frequency, the ramped voltage, the peak voltage, the voltage step, Vstep, the rising edge, the falling edge, and/or the fundamental period of the voltage waveform. The input may be a user interface or the input may be a communication link from a centralized controller.

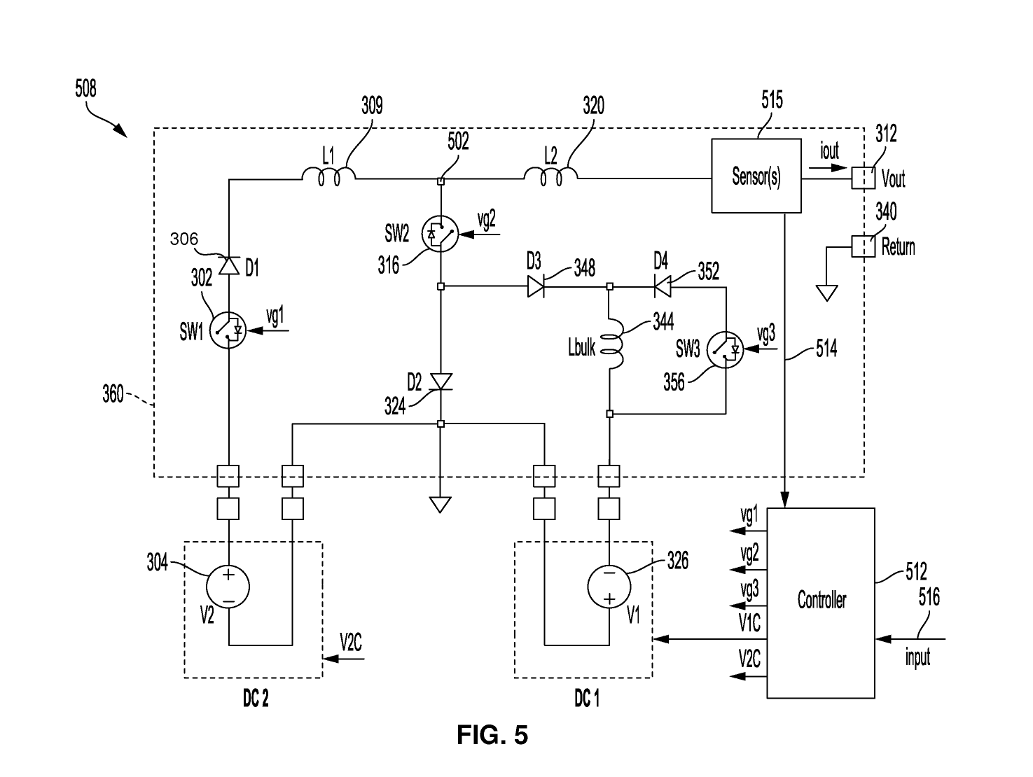

FIG. 5 shows an example of a bias supply 508. As shown, the bias supply 508 may comprise a topology that is similar to the topology 300 depicted in FIG. 3 and the topology 400 depicted in FIG. 4 except the first node of the second switch 316 is coupled to node 502, and both the second node of the first inductor 309 and the first node of the second inductor 320 may be coupled to node 502. As shown, the switches 302, 316, 356 may be implemented in switch section 360. And the power supplies 304, 326 may be removably coupled to the switch section 360. In other implementations, the power supplies 304, 326 may be integrated with other components of the bias supply 508, so that the switch section 360 is not a separately identifiable component of the bias supply 508. The power supplies 304, 326 may be DC power supplies. The power supplies 304, 326 may each be adjustable DC power supplies. One of the power supplies 304, 326 may be an adjustable DC power supply, and the other may be fixed. In other examples, both of the power supplies 304, 326 may be fixed.

The bias supply 508 may comprise a controller 512. The controller 512 may comprise metrology, data processing, and control logic. As shown by arrows, which represent communication links, the controller 512 can be coupled to the switches 302, 316, 356 to provide respective gate drive signals: vg1, vg2, and vg3. The controller 512 may be coupled to the first power supply 326 and the second DC supply 304 by communication links to enable the controller 512 to provide a first voltage control signal, V1C, and a second voltage control signal, V2C, to the first power supply 326 and the second power supply 304, respectively. The controller 512 may receive signals 514 indicative of one or more power-related parameters, such as, for example and without limitation, Vout and iout. The signals 514 may comprise signals indicative of one or more of forward power, reflected power, and phase. One or more sensors 515 may provide the signals 514. The one or more sensors 515 may be coupled to the first node 312 of the bias supply 508. The node 312 may be an output of the bias supply 508. The one or more sensors 515 may be realized by, for example and without limitation, sensors that provide information indicative of voltage and/or current at a node of the bias supply 508. For example, and without limitation, the one or more sensors 515 may comprise a VI sensor, a directional coupler and/or by separate voltage and current sensors.

The controller 512 may control a voltage, v1, of the first power supply 326 by controlling the first voltage control signal, V1C. The controller 512 may control a voltage, v2, of the second power supply 304 by controlling the second voltage control signal, V2C. The controller 512 may receive input 516 that provides, for example, one or more setpoints to the controller 512. The setpoints, for example, may define one or more aspects of the voltage waveform at Vout. The one or more controlled aspects may comprise the duty cycle, frequency, the ramped voltage, the peak voltage, the voltage step, Vstep, the rising edge, the falling edge, and/or the fundamental period of the voltage waveform. The input 516 may be a user interface or the input 516 may be a communication link from a centralized controller. Although not shown in FIGS. 3 and 4, the topology 300 depicted in FIG. 3 and the topology 400 depicted in FIG. 4 may be implemented in connection with the controller 512.

Referring next to FIGS. 6A - 6E, shown are timing diagrams depicting operational aspects for the topologies depicted in FIGS. 3 and 4 and the bias supply 508 depicted in FIG. 5. FIGS. 6A - 6E depict, for a particular time window, the timing that may be used for a first gate drive signal, vg1, that is provided to the first switch 302; the timing of a second gate drive signal, vg2, that is provided to the second switch 316; and timing of a third gate drive signal, vg3, that is provided to the third switch 356. In the time window for each of FIGS. 6A - 6E, a portion of each gate drive signal, the voltage waveform, Vout, output current, iout, and substrate voltage, v_substrate, is shown by a thickened line relative to other lines in the timing diagram.

The gate drive signals vg1, vg2, vg3 correspond, respectively, to positions of the switches 302, 316, 356. For example, a high signal level indicates that the switch is closed and a low signal level indicates that the switch is open. As an example, as depicted in FIGS. 6A - 6E, both the first switch 302 and the third switch 356 are initially closed from time t0 to t2 because both corresponding signals, vg1 and vg3, are high. Also shown in FIGS. 6A - 6E is the voltage waveform, Vout, produced during each particular time window, in response to the depicted gate drive signals. In addition, the output current, iout, is shown during each particular time window. Also depicted during each particular time window is a voltage at a surface of a substrate, V_substrate, which may be the sheath voltage between a plasma 102 within the plasma chamber 101 and the surface of the workpiece 103. In addition, FIGS. 6A - 6E also comprise arrows depicting, during each particular time window, a direction of current that occurs.

As shown, at t0, when the first switch 302 and the third switch 356 are closed and the second switch 316 is open, Vout may change until a peak voltage is reached at t2, and then at t2, the first switch 302 is opened while the third switch 356 remains closed. As shown in FIG. 6A, during the rising edge of the waveform, Vout, the voltage at the substrate, V_substrate, may decrease in magnitude from the first negative voltage 121 and approach zero volts. At t1, the voltage at the substrate, Vsubstrate, may reach approximately zero volts. In some embodiments, the voltage of the waveform, Vout, may become positive at t1.

As shown in FIGS. 6A and 6B, from t0 to t2, the direction of current within current paths of the topology may remain the same. From t0 to t2, the current, iout, may be positive current (moving in the direction of the arrow out of the node 312 in the direction of a load (not shown in FIGS. 6A through 6E)). From t0 to t2, the output current, iout, may increase, reach a positive maximum, pmax, and then decrease to zero amps when the first switch 302 is opened at t2.

From t2 to t3, the voltage waveform, Vout, may stay, without any voltage droop, approximately at the peak voltage at node 312 and the output current, iout, may remain at approximately zero amps. From time t2 to t3, the switch section 360 may operate to substantially disconnect any current between the switch section 360 and any load coupled to node 312. As shown, in FIG. 6C, from time t2 to t3, the switch section 360 may operate to neither provide current to the first node 312 nor receive current via the first node 312 while Vout 312 is at the peak voltage. As shown in FIG. 6C, the first switch 302 may open at t2, the second switch 316 may remain open, and the third switch 356 may remain closed. As shown, current may circulate from time t2 to t3 in a loop comprising the fourth diode 352, the third inductor 344 and the third switch 356.

At t3, the second switch 316 may be closed and the third switch 356 may be opened to initiate a change in the waveform voltage, Vout, represented by Vstep 132. As shown in FIG. 6D, between times t3 and t4, the output current, iout, may increase in magnitude in a negative direction where the negative direction is in the direction of node 312 from a load. The output current, iout, may increase in magnitude to a negative peak current, nmax. And then the output current, iout, may decrease in magnitude to a compensation current, icomp. As shown, the negative output current, iout, may flow during a time window from t3 to t4 though node 312 through second inductor 320, through second diode 324, and to the return node 340.

At t4, the voltage step 132 may end, and from t4 to t5, the voltage waveform, Vout may be the ramped voltage 128. The ramped voltage 128 may have a negative slope. From t4 to t5, the output current, iout, may remain at -Icomp during the ramped voltage. From t4 to t5, the third diode 348 may be on. From t4 to t5, the output current, iout, may be negative and may flow into the topology through the second inductor 320, through the third diode 348, and through the third inductor 344 When the load coupled to node 312 comprises the plasma processing chamber 101, the output current, iout, may compensate for a positive charge built up on the workpiece 103 due to positive ions impacting the workpiece 103. As shown in FIG. 6E, when the compensation current, -Icomp, is equal to the ion current, a sheath voltage at the workpiece 103 may be a substantially constant voltage. When the compensation current, -Icomp, is less than the ion current, a sheath voltage at the workpiece 103 may comprise a positive voltage slope. When the compensation current, -Icomp, is greater than the ion current, a sheath voltage at the workpiece 103 may comprise a negative voltage slope. A magnitude of a voltage output by the first power supply 326 may be adjusted to adjust the compensation current, -Icomp, in the time window from t4 to t5.

In the example voltage waveform, Vout, depicted in FIGS. 6A - 6E, Vout remains substantially at the peak voltage from t2 to t3 with little or no droop or slope. In other examples, the peak voltage may experience droop, such as depicted in FIG. 2.

In some examples of the bias supply 508, the controller 512 may provide independent controls for an ion energy distribution function (IEDF), slope of the ramped voltage (for current compensation), frequency, and duty cycle. The IEDF can be characterized as a distribution of ion energies in the plasma processing chamber 101 that result from the waveform at Vout being applied to the workpiece 103.

The duty cycle of the voltage waveform may be adjusted by changing the duration of the switch states for the first switch 302, the second switch 316, and the third switch 356 after the peak voltage 122 is reached. The magnitude of Vstep 132 may be set by the magnitude of voltage, V2, output by the second power supply 304. Regulating the voltage, V2, may provide control over the IEDF. The current compensation may be set by adjusting the value of voltage, V1, provided by the first power supply 326. The combination of the voltage ,V1, and inductor 344 (also referred to as Lbulk) may provide a regulated current source that may provide current compensation (-Icomp) during the ramped voltage 128. The frequency of the voltage waveform, Vout, at node 312 may be controlled by controlling the first switch 302 and the second switch 316.

The stress on the first switch 302 and the second switch 316 may be relatively low stress such as, for example, the stress seen on a bias supply with a single switch and a single power supply. The voltage across the first switch 302 can be a relatively low voltage, and the current through the third switch 356 can be a relatively low current. Each of the first power supply 326 and the second power supply 304 can have a peak power in the range of 16 kilowatts (kW) to 18 kW. Each of the power supplies 326, 304 can operate at less than 3000 volts. Each of the power supplies 326, 304 can operate at less than 8 amps of total DC current. In variations, the power supplies 326, 304 may be bidirectional power sources. When implemented as bidirectional power sources, the power supplies 326, 304 may enable the voltage, V2, provided by the second power supply 304 to extend a compensated operating area to edges at a low Vstep, high current, and low frequency.

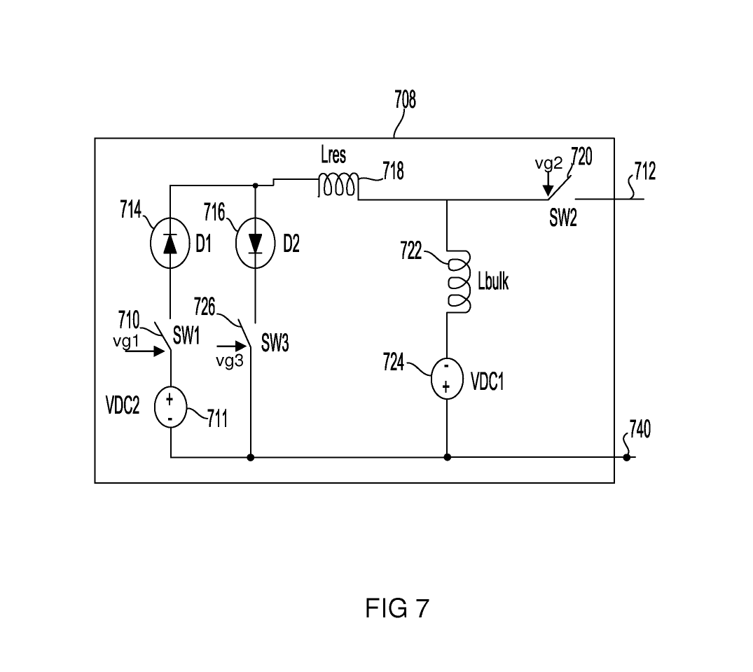

Referring next to FIG. 7, shown is another example bias supply 708 that utilizes another circuit topology. As shown, the topology comprises a first switch 710 that is coupled between a positive node of a first power supply 724 (e.g., a DC power supply) and an anode of a first diode 714, and a cathode of the first diode 714 is coupled to an anode of a second diode 716 and a first node of a first inductor 718. A second switch 720 is coupled between an output 712 of the bias supply 708 and a second node of the first inductor 718. The second node of the first inductor 718 is also coupled to a first node of a second inductor 722, and a second node of the second inductor 722 is coupled to a negative node of a first power supply 724. In addition, a third switch 726 is coupled between a cathode of the second diode 716 and a negative node of the first power supply 724. The negative node of the first power supply 724 is coupled to a positive node of the second power supply 711. A common node coupled to the positive node of the first power supply 724 and the negative node of the second power supply 711 may be coupled to a return node 740, which may be ground. In some examples, the first diode 714 and the second diode 716 may each be instantiated as a body diode of the first and second switches, respectively. That is, the first switch 710 and the second switch 726 may be connected such that the body diode of each switch is oriented as shown in FIG. 7. Although the second power supply 711 is depicted with a polarity that functions to source power, it should be recognized that the second power supply 711 may be a bidirectional power supply that may also sink power.

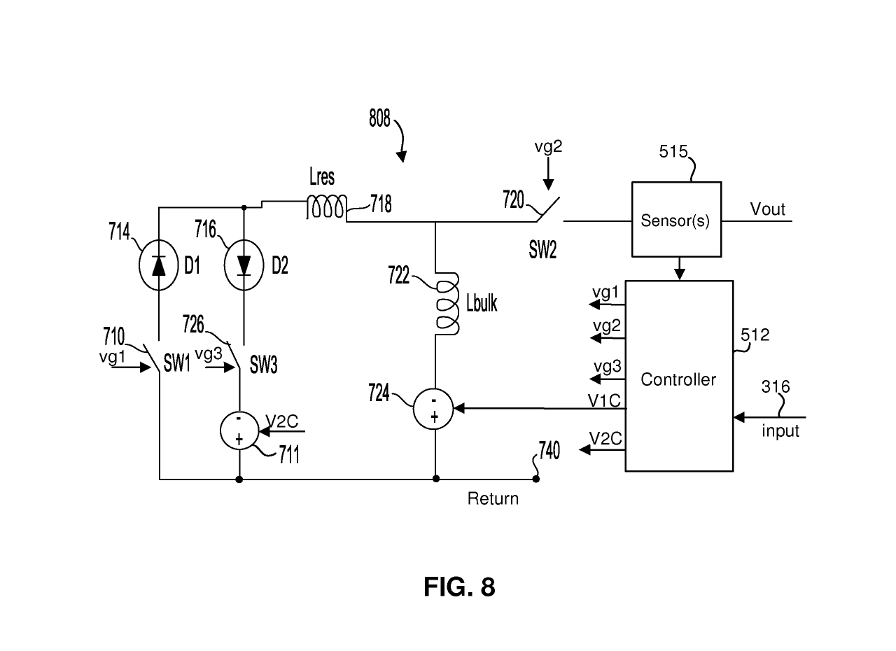

Referring to FIG. 8, shown is another example of a bias supply 808. As shown, the bias supply 808 may comprise the same topology as the bias supply 708 except the first power supply 724 is coupled between the third switch 726 and the return node 740. The three switches 710, 720, and 726 can be implemented in a switch section (not shown in FIG. 8) and the power supplies 711 and 724 can be removably coupled to the switch section. In other implementations, the power supplies 711 and 724 may be integrated with other components of the bias supply 808 so that the switch section is not a separately identifiable component of the bias supply 808. The power supplies 711 and 724 can be DC power supplies. The power supplies 711 and 724 may each be adjustable DC power supplies. One of the power supplies, 711 and 724, may be an adjustable DC power supply and the other may be fixed. In other examples, both of the power supplies 711 and 724 may be fixed. Although the second power supply 711 is depicted with a polarity that functions to source power, it should be recognized that the second power supply 711 may be a bidirectional power supply that may also sink power.

Each of the switches 710, 720, and 726 generally represents one or more switches that may be capable of closing and opening to connect and disconnect, respectively, a current pathway. For example, a single depicted switch may be realized by a plurality of switches arranged in series (for enhanced voltage capability), may be realized by a plurality of switches arranged in parallel (for enhanced current capability), or the single switch may be comprised of a plurality of switches arranged in a series-parallel combination (for enhanced voltage and/or current capability). In these variations, each switch that is used to realize a particular one of the switches 710, 720, and 726 may be synchronously driven by a corresponding drive signal. Each of the switches 710, 720, and 726 depicted in FIG. 7 can be of the same type as the switches 302, 316, and 356 described with reference to FIGS. 3 and 4.

As shown, the bias supply 808 can include the controller 512 to control the bias supply 808. When utilized in connection with the bias supply 808, the controller 512 can operate in much the same way as the controller 512 as described with reference to FIG. 5 except that the timing for the switches and control of the power supplies can be different. The one or more sensors 515 and the controller 512 may be utilized to control the switches 710, 720, and 726 and power supplies 711, 724 shown in FIG. 7

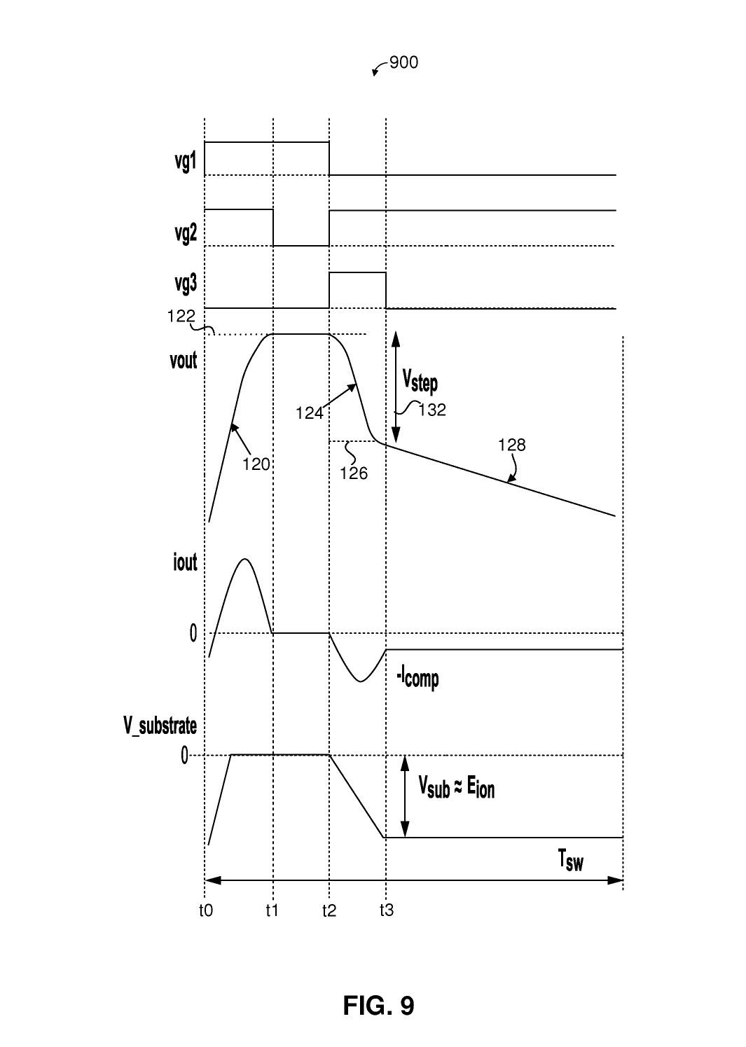

Referring next to FIG. 9, shown is a timing diagram 900 that depicts the timing of the first gate drive signal, vg1, that is provided to the first switch 710; the second gate drive signal, vg2, that is provided to the second switch 720; and the third gate drive signal, vg3, that is provided to the third switch 726.

As shown, at t0, when the first switch 710 and the second switch 720 are closed and the third switch 726 is open, Vout may change until the peak voltage 122 is reached at t1, and then at t1, the second switch 720 can be opened while the first switch 710 remains closed. From t1 to t2, Vout may stay substantially at the peak voltage, then at t2, the second switch 720 and the third switch 726 can be closed and the first switch 710 can be opened to initiate a change in Vout represented by Vstep. At t3, the third switch 726 can be opened and Vstep 132 may end. From t3 to t4, the second switch 720 can remain closed while the first switch 710 and the third switch 726 can remain open. From t3 to t4, Vout may be the ramped voltage 128. The ramped voltage 128 may have a negative slope. In the example output voltage waveform, Vout, depicted in FIG. 9, Vout remains substantially at the peak voltage 122 from t1 to t2 with little or no droop or slope. In other examples, the peak voltage may experience droop, such as depicted in FIG. 1B.

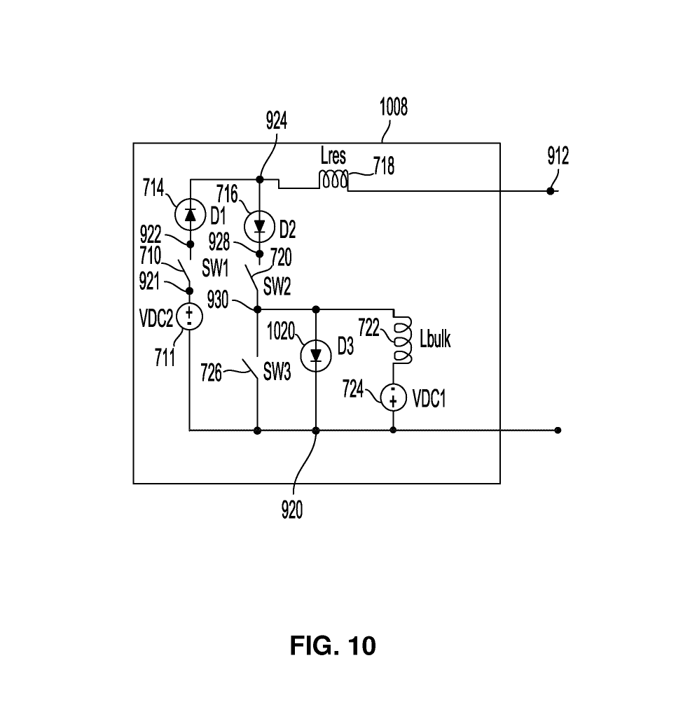

Referring next to FIG. 10, shown is another example bias supply 1008 that comprises another example circuit topology. As shown, the first power supply 724 is coupled between node 920 and node 921, the first switch 710 is coupled between node 921 and node 922, the first diode 714 is coupled with an anode at node 922 and a cathode at node 924, the first inductor 718 is coupled between the node 924 and node 912, second diode 716 is coupled with an anode at node 924 and a cathode at node 928, second switch 720 is coupled between node 928 and node 930, third switch 726 is coupled between node 920 and node 930, a third diode 1020 is coupled with an anode at node 930 and a cathode at node 920, and a series arrangement of second inductor 722 and a second power supply 711 is arranged between node 920 and node 930, and node 920 may be a return node coupled to ground. As described herein, first diode 714, second diode 716, and third diode 1020 may be implemented as body diodes of the corresponding first switch 710, second switch 720, and third switch 726. Although the second power supply 711 is depicted with a polarity that functions to source power, it should be recognized that the power supply 711 may be a bidirectional power supply that may also sink power.

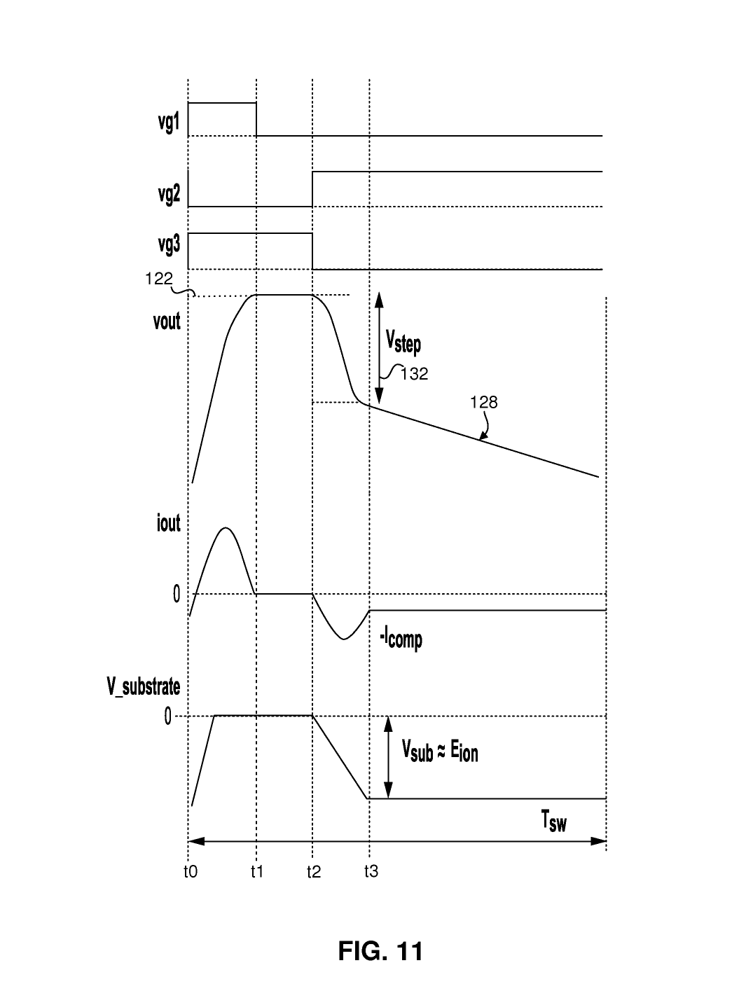

FIG. 11 is an example timing diagram for the operation of the example bias supply 1008. As shown, when the first switch 710 and the third switch 726 are closed and the second switch 720 is open, the voltage of the voltage waveform. Vout, changes until the voltage reaches the peak voltage 122 and then the first switch 710 is opened, and then the second switch 720 is closed and the third switch 726 is opened to initiate a voltage change depicted by the voltage step Vstep 132 and the second switch 720 remains closed while the first switch 710 and the third switch 726 are open for the duration of the ramped voltage 128. As one of ordinary skill in the art will appreciate, the duty cycle may be adjusted by adjusting when the second switch 720 is closed and when the third switch 726 is opened. As shown in FIG. 11, once the peak voltage 122 is reached, the voltage of the voltage waveform, Vout, may be maintained substantially constant until the change for the voltage step 132 is initiated.

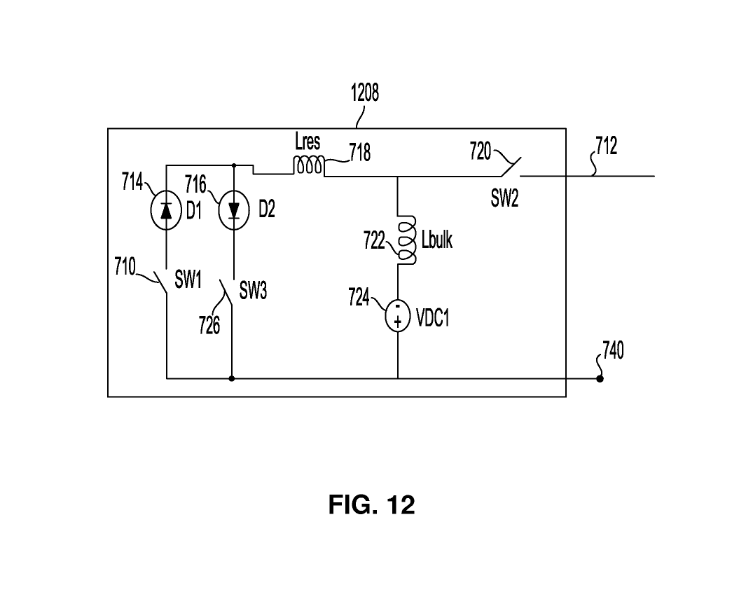

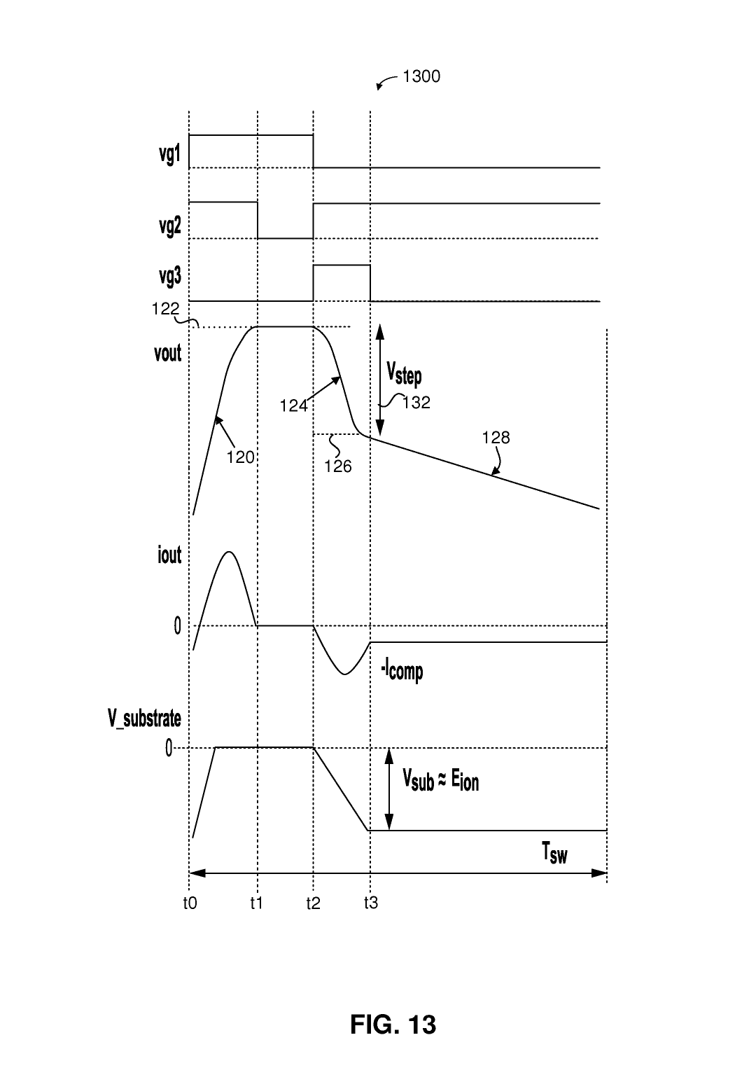

Turning next to FIG. 12, it depicts yet another example bias supply 1208, which comprises a topology that is similar to the topology of the bias supply 708 depicted in FIG. 7 except the first power supply 724 is removed. The timing diagram 1300 in FIG. 13 for the switches of the bias supply 1208 may be substantially the same as, or similar to, the timing diagram for the switches of the bias supply 708. As shown in FIG. 13, the first gate drive signal, vg1, is provided to the first switch 710; the second gate drive signal, vg2, that is provided to the second switch 720; and the third gate drive signal, vg3, that is provided to the third switch 726 of FIG. 12.

As shown, at t0, when the first switch 710 and the second switch 720 are closed and the third switch 726 is open, Vout may change until the peak voltage 122 is reached at t1, and then at t1, the second switch 720 can be opened while the first switch 710 remains closed. From t1 to t2, Vout may stay substantially at the peak voltage, then at t2, the second switch 720 and the third switch 726 can be closed and the first switch 710 can be opened to initiate a change in Vout represented by Vstep. At t3, the third switch 726 can be opened and Vstep 132 may end. From t3 to t4, the second switch 720 can remain closed while the first switch 710 and the third switch 726 can remain open. From t3 to t4 Vout may be the ramped voltage 128. The ramped voltage 128 may have a negative slope. In the example output voltage waveform, Vout, depicted in FIG. 13, Vout remains substantially at the peak voltage 122 from t1 to t2 with little or no droop or slope. In other examples, the peak voltage may experience droop, such as depicted in FIG. 1B.

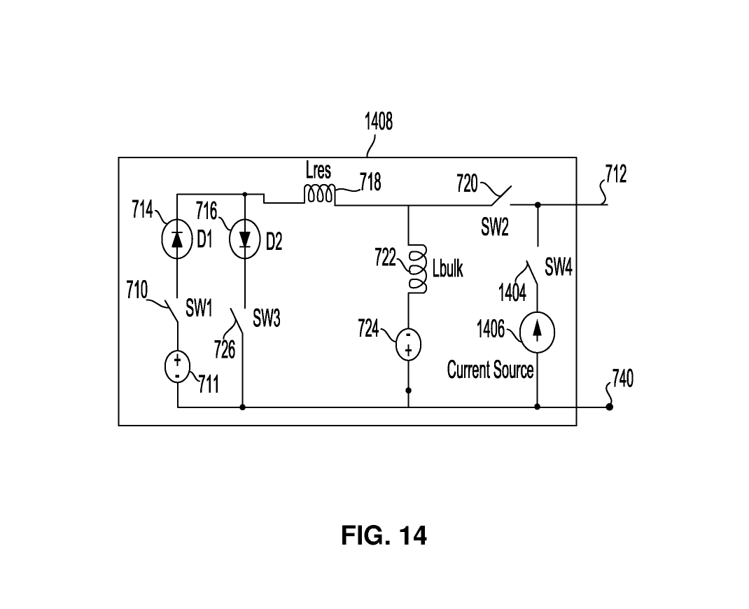

Referring to FIG. 14, it depicts another example bias supply 1408. As shown, the bias supply 1400 is the same as the bias supply 700 depicted in FIG. 7 except that a series arrangement of a current source 1406 and a fourth switch 1404 is coupled between an output node 712 and the positive node of the first power supply 724. The current source 1406, when connected to the output node 712 of the bias supply 1408 may provide additional control of aspects of the output waveform, such as control of aspects of the voltage droop (e.g., to eliminate voltage droop). Although the power supply VDC1 is depicted with a polarity that functions to source power, it should be recognized that the power supply VDC1 may be a bidirectional power supply that may also sink power.

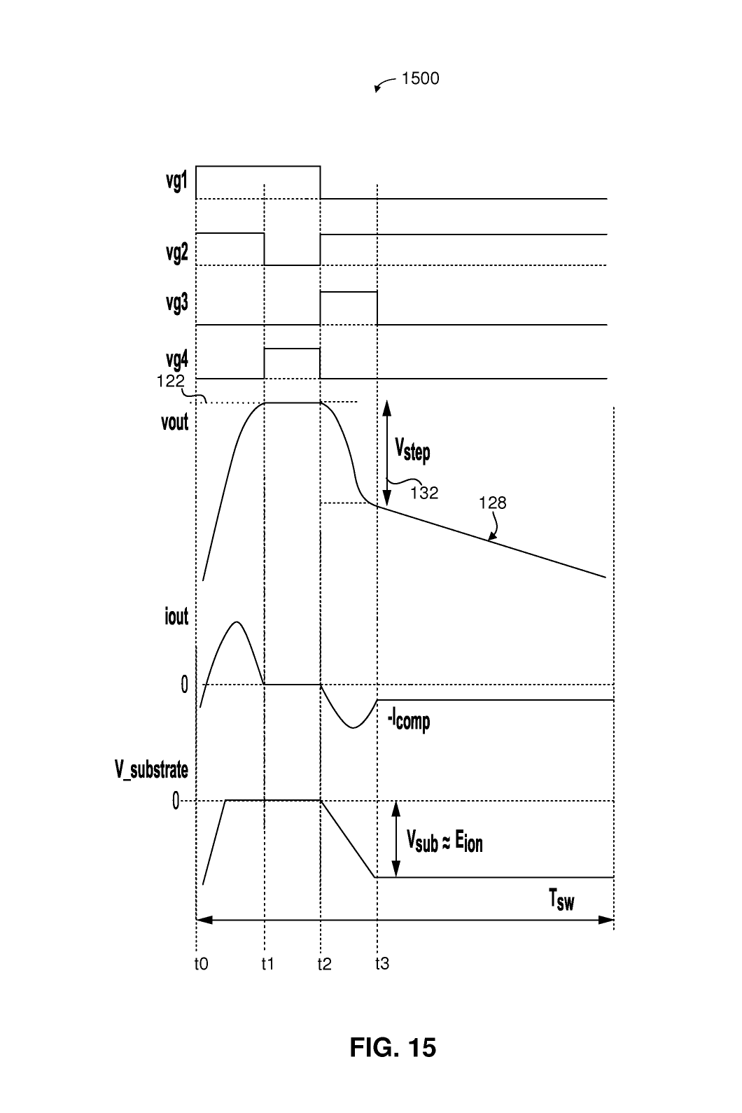

FIG. 15 depicts a timing diagram for the operation of the switches of the bias supply 1400. As depicted, the timing of the first switch 710, the second switch 720, and the third switch 726 is the same as the timing for the same switches in the bias supply 700, As shown in FIG. 15, the first gate drive signal, vg1, is provided to the first switch 710; the second gate drive signal, vg2, that is provided to the second switch 720; and the third gate drive signal, vg3, that is provided to the third switch, 726, and a fourth gate drive signal is provided to the fourth switch 1404.

As shown, at t0, when the first switch 710 and the second switch 720 are closed and the third switch 726 is open, the voltage waveform, Vout, may change until the peak voltage 122 is reached at t1, and then at t1, the second switch 720 can be opened while the first switch 710 remains closed. Additionally, the fourth switch 1404 may be closed from t1 to t2, and the voltage waveform, Vout, may stay substantially at the peak voltage 122, then at t2, the second switch 720 and the third switch 726 can be closed, the first switch 710 and the fourth switch can be opened to initiate a change in the voltage waveform, Vout, represented by Vstep 132. At t3, the third switch 726 can be opened and Vstep 132 may end. From t3 to t4, the second switch 720 can remain closed while the first switch 710 and the third switch 726 can remain open. From t3 to t4 Vout may be the ramped voltage 128. The ramped voltage 128 may have a negative slope. In the example output voltage waveform, Vout, depicted in FIG. 15, Vout remains substantially at the peak voltage 122 from t1 to t2 with little or no droop or slope. In other examples, the peak voltage may experience droop, such as depicted in FIG. 1B.

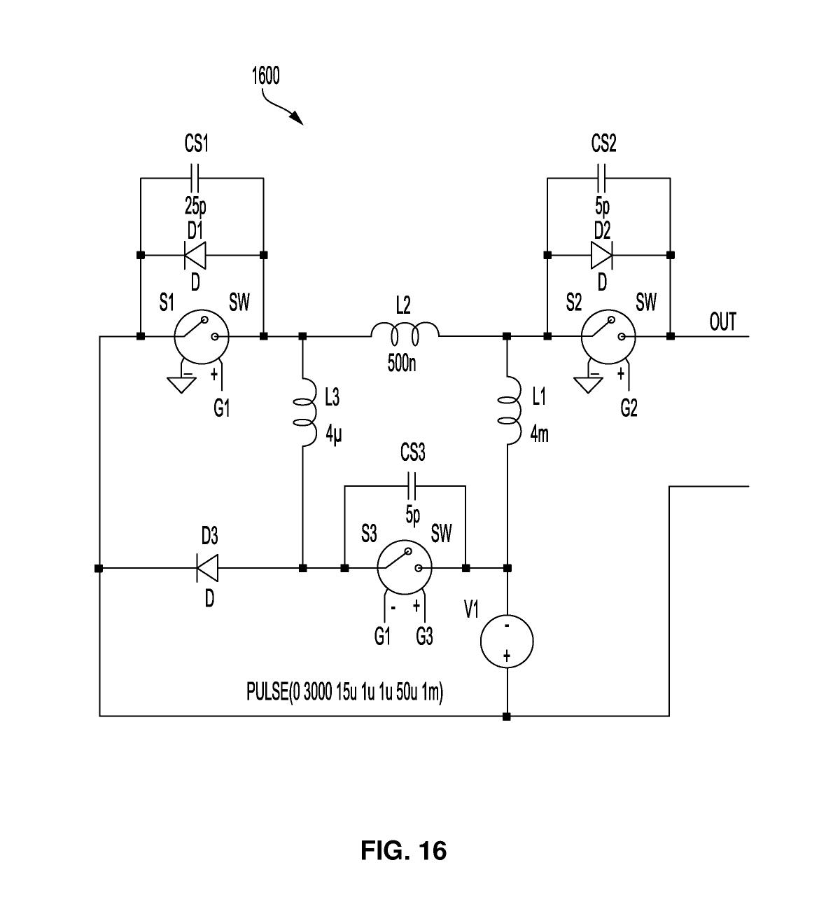

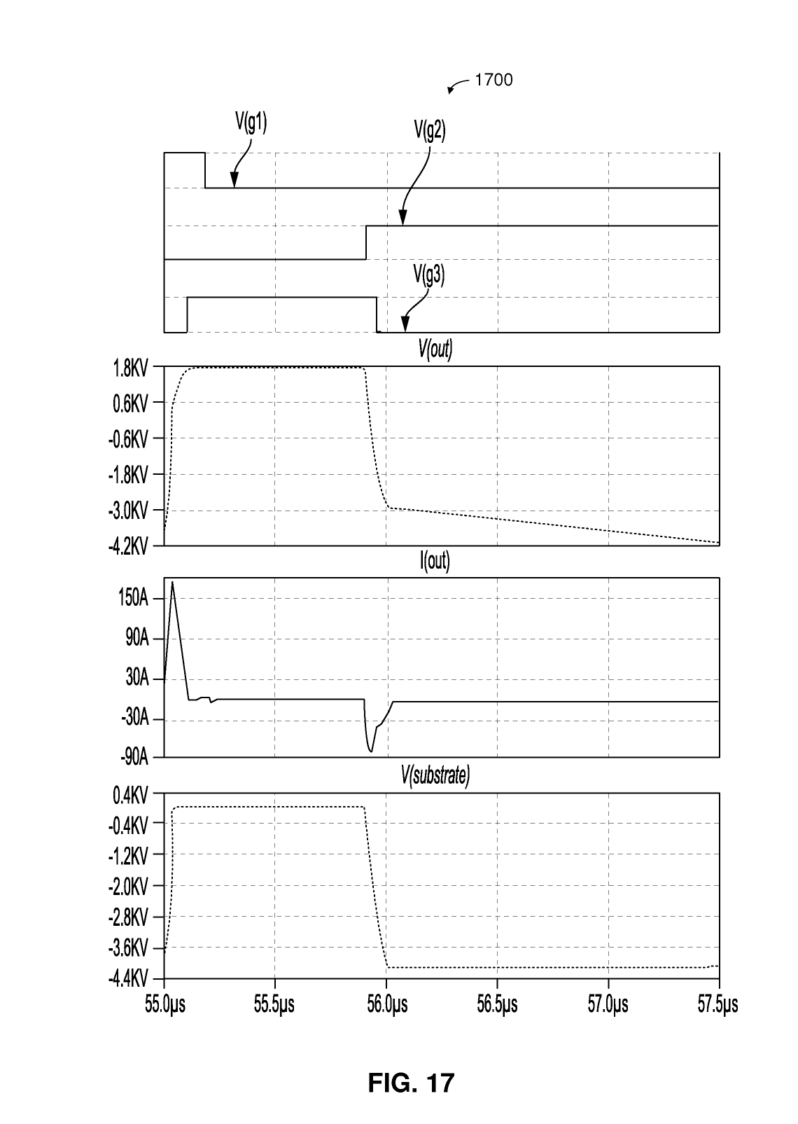

FIG. 16 shows an example topology 1600, which may be referred to as a falling edge buck converter, according to various aspects of the present disclosure. As shown, this particular topology may comprise a voltage source, V1, and three switches: S1, S2, and S3. In some cases, this topology 1600 may employ switch overlap, which may entail simultaneously keeping both the high-side (HS) switch and low-side (LS) switches in an ON state during the switching transition. In some cases, the switch overlap shown and described in relation to FIG. 17 may further include shorting the inductor L1. In some examples, the block diagram shown and described in relation to FIG. 16, may further employ a “high turn off current” action, which is typically associated with discontinuous mode (DCM) buck converters. In some cases, the switch overlap buck action may be implemented on the negative/falling edge. In some cases, such a falling edge buck converter can help simplify implementation of the control switching loop, thereby resulting in lower costs to both the fabrication lab utilizing such equipment/system, as well as the risk of failure (e.g., loss of entire substrate, loss of critical components) during wafer processing. It should be noted that other advantages not discussed herein can also be attributed to the simpler and easier to implement control switching loop (or simply switching loop), such as, but not limited to, easier maintenance of the buck converter coupled to the input of a load (e.g., plasma processing chamber 101).

As shown in FIG. 16, a switch S1 is coupled at one end to the junction of inductors L2 and L3, and at another end to the cathode of diode D3. Furthermore, the opposing end of inductor L2 is coupled to one end of inductor L1, while the opposing end of inductor L1 is coupled to one end of the switch S3 and the negative terminal of supply V1. In some examples, the power supply V1 (also referred to as a voltage source V1) may be an adjustable DC power supply and may provide a range of voltages. In other examples, power supply V1 may be a fixed voltage power supply. As seen, the opposing end of switch S3 is coupled to the junction of the anode of diode D3 and an opposing end of inductor L3. Here, the positive terminal of power supply V1 and the cathode of diode D3 are coupled to a reference voltage, such as the ground voltage. The ground voltage is more clearly seen in FIG. 11.

As shown in FIG. 16, S1 is coupled at one end to an anode of a diode D1 and at another end to the cathode of the diode D1. The cathode of diode D1 is further coupled to the cathode of diode D3, while the anode of diode D1 is coupled to the junction of inductors L2, L3. Furthermore, the other end of inductor L2, i.e., the end coupled to one end of the inductor L1 is further coupled to one end of the switch S2 and an anode of diode D2. The cathode of diode D2 and the opposing end of switch S2 are coupled to the output. In further embodiments, the first and/or second diodes D1, D2 may be realized as body diodes associated with the first switch and second switch, respectively, for example, when the first and second switches are implemented as MOSFETs. In other embodiments, such as depicted, the second diode D2 may be implemented as a separate component. It should be noted that other switches besides MOSFETS may be realized as any of a variety of possible switches, such as relays IGBTs, and the like. While the first and second switches are each depicted as including a snubber network, such a network is not required, and should not be viewed as limiting. In some cases, the switches S1 and/or S2 may be coupled to a controller (shown by gates G1 and G2).

Continuing with FIG. 16, a controller (not shown in FIG. 16) may be used to control the switches and power supply, V1, and the controller may comprise metrology, data processing, and control logic. The controller may be coupled to a gate of the first switch, S1, and a gate of the second switch, S2, so that the controller may provide gate signals (shown as v(g1), v(g2), and v(g3) in FIG. 17) to the switches. The controller is also coupled by a communication line to the DC power supply V1 to enable the controller to adjust a voltage of the DC power supply. The controller may control the gate drive signals to each of the switches and/or may control the DC voltage of the power supply based upon feedback from a sensor. As one of ordinary skill in the art will appreciate, the sensor may be realized by a variety of sensors that provide information indicative of voltage and/or current at the output of the bias supply. For example, and without limitation, the sensor may be realized by a VI sensor, a directional coupler or by separate voltage and current sensors.

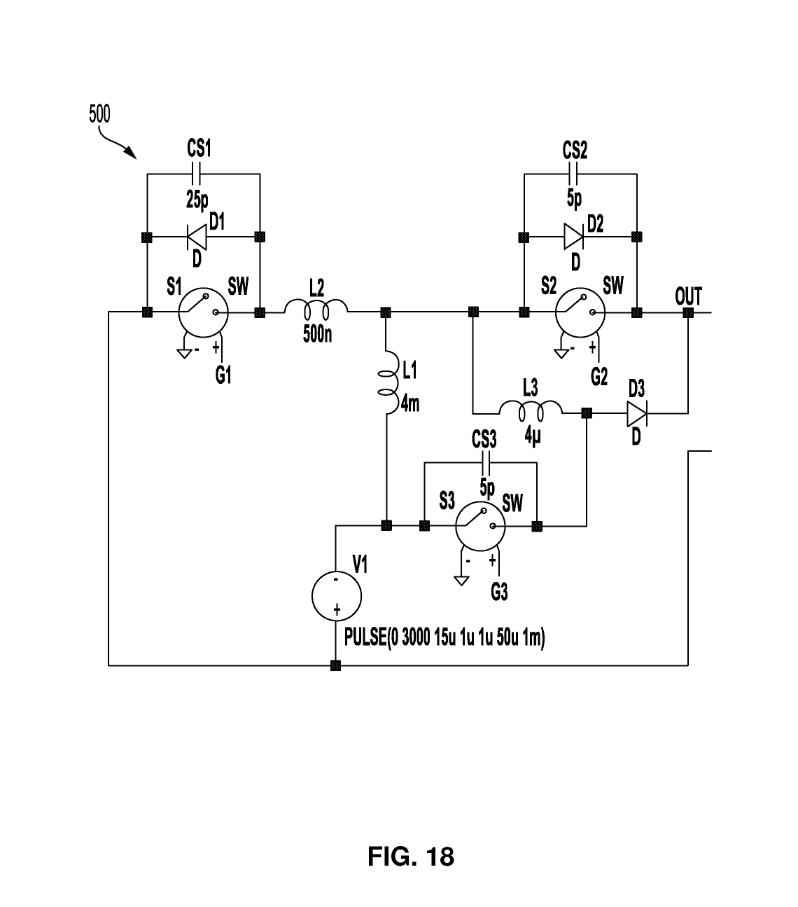

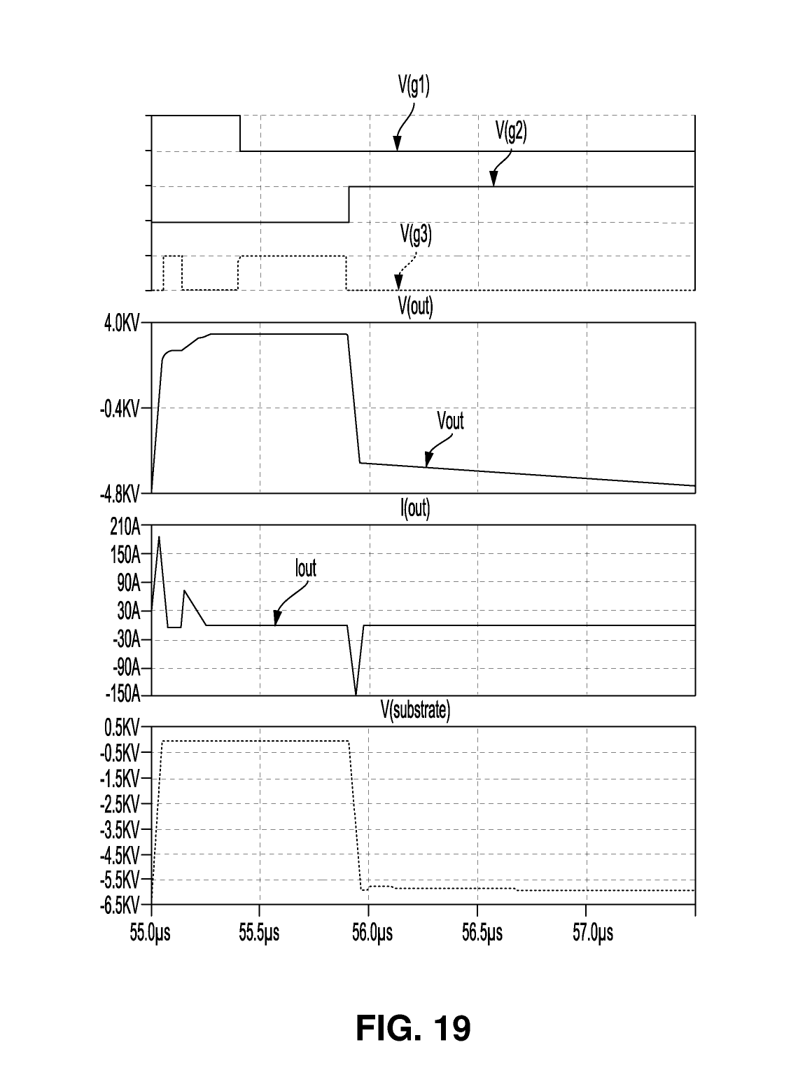

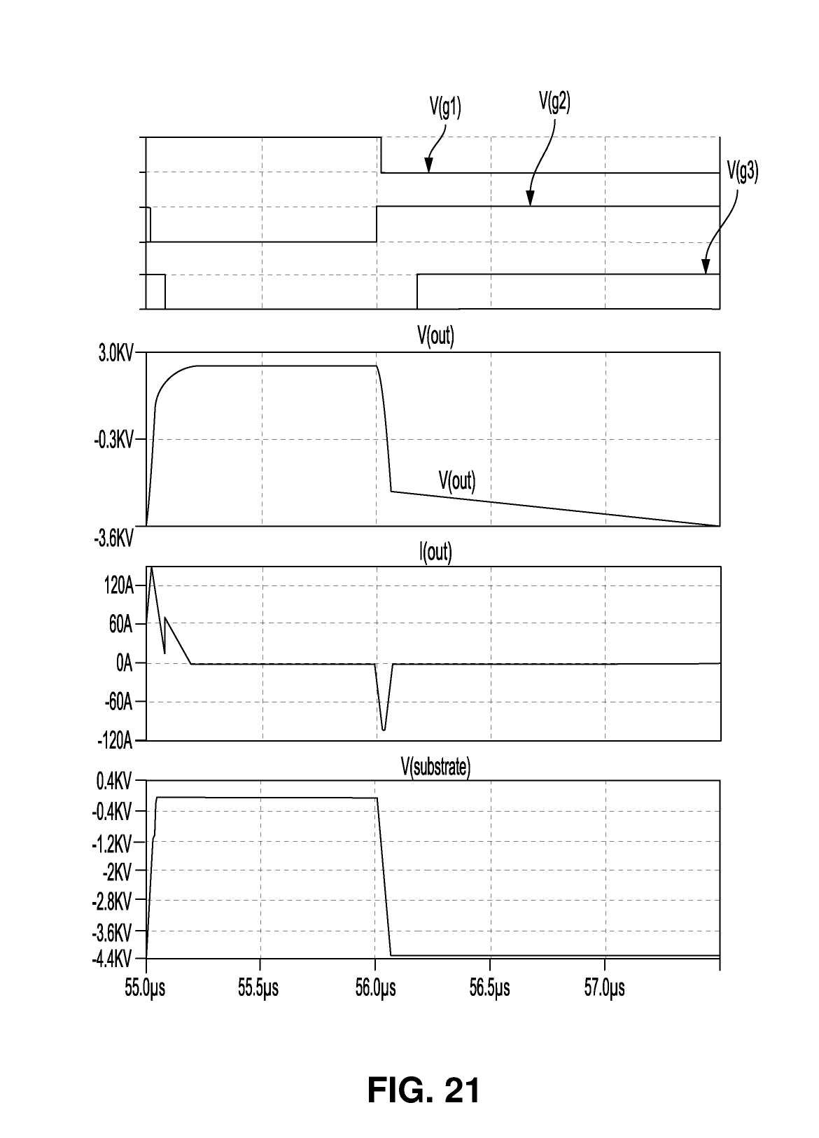

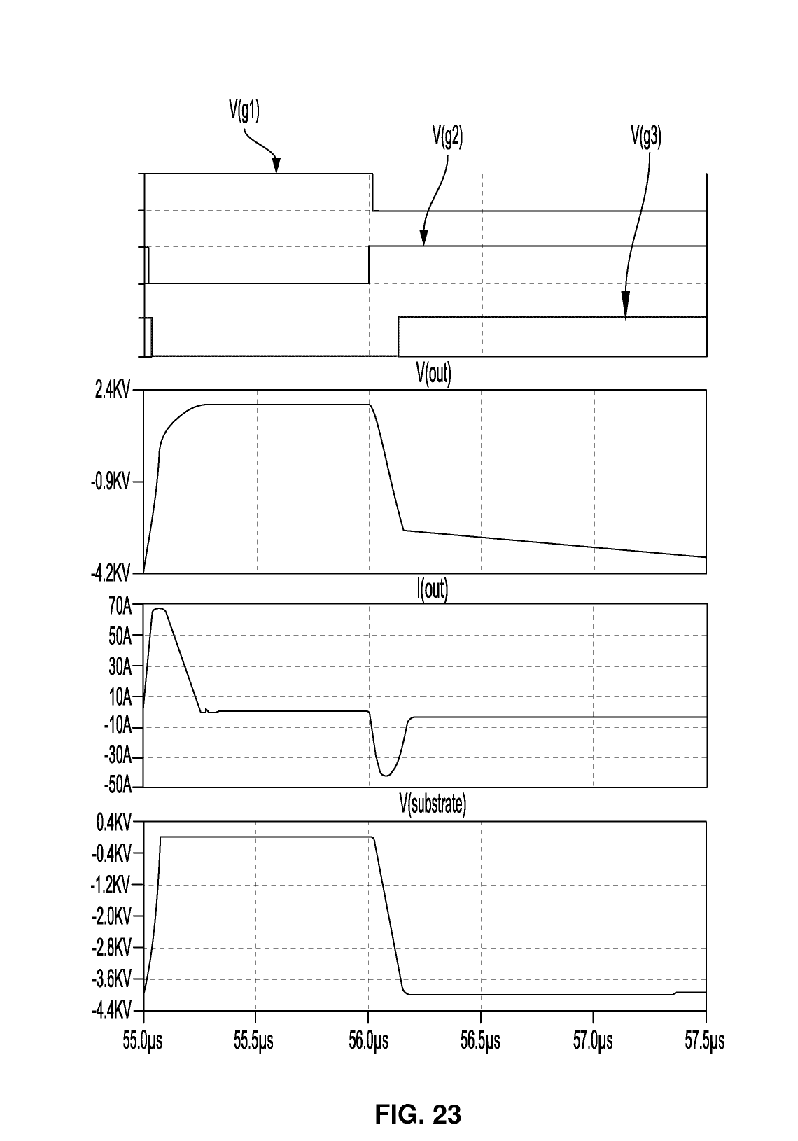

FIG. 17 shows a conceptual graph 1700 in the form of a timing diagram that depicts the timing of a first gate drive signal V(g1) that is provided to the first switch S1 in FIG. 16 and a second gate drive signal V(g2) that is provided to the second switch S2 of the falling edge buck converter. As depicted in FIG. 17, the first switch, S1, is initially closed and the second and third switches are initially open (e.g., V(G1) = high, both V(G2) and V(G3) = low). Also shown is a voltage waveform (Vout) produced in response to the depicted gate drive signals. In addition, the output current (Iout) of the converter and a voltage at a surface of a substrate (Vsubstrate), which may be the sheath voltage between a plasma within a plasma chamber and the surface of the substrate is also shown. Similarly, FIGS. 19, 21, and 23 show similar timing diagrams of the gate voltages, output voltage (Vout), output current (Iout), and substrate voltage (Vsubstrate) for the topologies in FIGS. 18, 20, and 22 discussed further herein.

Aspects of the present disclosure can employ switch overlap techniques (i.e., when both the high side and low side of the switch, such as a metal-oxide-semiconductor field-effect transistor or MOSFET, are simultaneously ON during the switching transition on the positive edge) and/or a rising/positive edge buck-boost converter. In other words, similar to the switch overlap on the negative/falling edge of a buck converter (described above in relation to FIG. 16), a similar or substantially similar switch overlap technique may be deployed on boost and/or buck-boost converters, where the switch overlap is now utilized for the rising/positive edge.

Referring to FIG. 16, shown is another topology 1600. The topology may also be referred to as a rising edge boost converter 1600 or alternatively a boost converter 1600. As seen, the boost converter 1600 may comprise a first switch (S1) and a second switch (S2), where each of the first and second switches (S1, S2) can be turned ON (to allow current flow) or OFF (to block current flow) using the gate-voltage of the switch (e.g., MOSFET, or another applicable transistor). Specifically, the gate voltages G1, G2 of switches S1, S2, respectively (shown in FIG. 17 as v(g1) and v(g2), can be used to control the flow of current between the source and drain terminals of the corresponding switches. In this example, a third switch S3 is also provided that can be toggled between an ON/OFF state based on applying a sufficient gate-source voltage (shown in FIG. 17 as v(g3)) to G3.

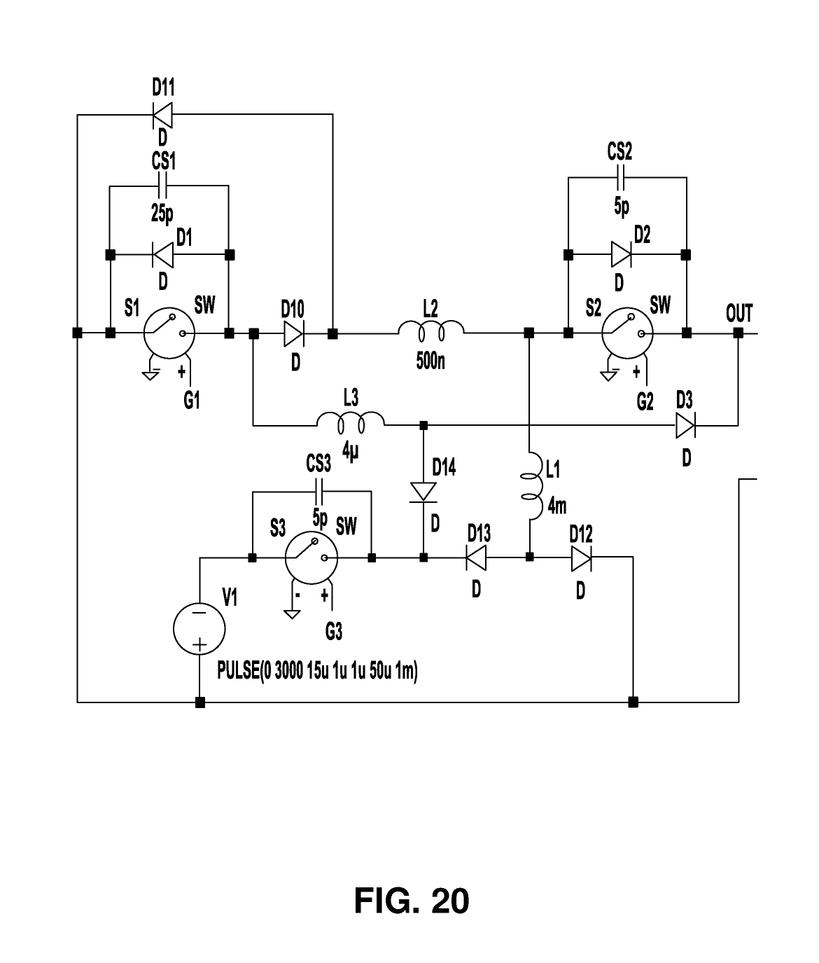

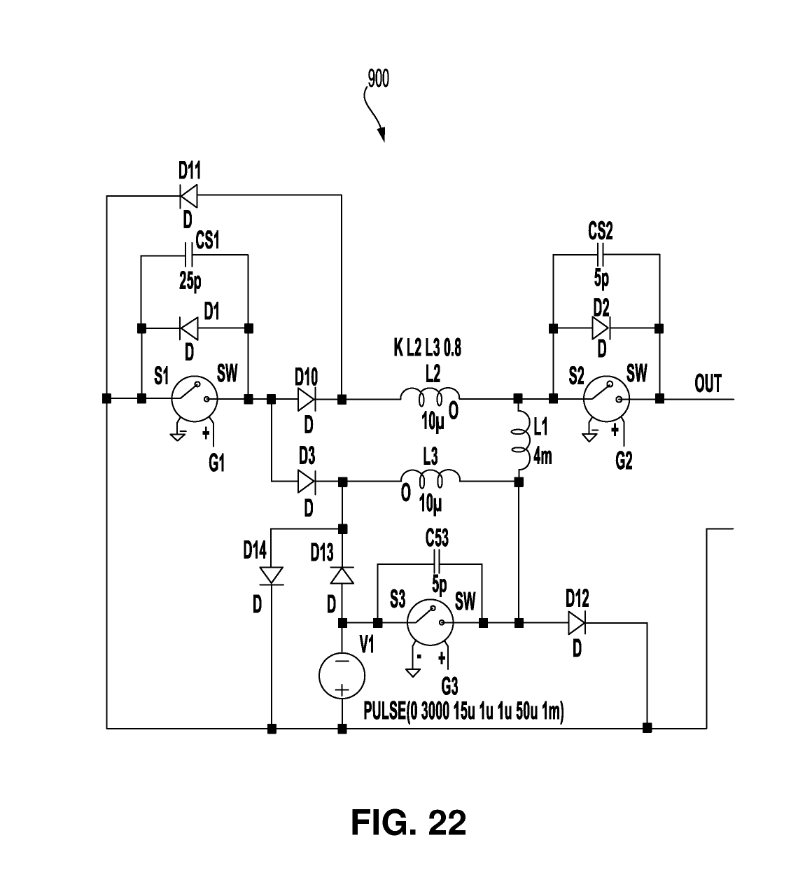

It should be noted that the CSx capacitors, where x is an integer value (e.g., CS1 capacitor across switch S1, CS2 capacitor shown across switch S2) are included for simulation purposes only (e.g., to accurately model the behavior of the switch S1 by inclusion of its intrinsic capacitance, CS1). That is, the CSx capacitors shown across the switches are not fundamentally required for the operation of the various topologies described herein. Furthermore, it should be noted that the various topologies depicted and described herein use a similar labeling convention with respect to the switches, where the switch S1 may be utilized for the rising edge, the switch S2 may be utilized for control of duty cycle and the falling edge, and switch S3 may be utilized for reducing the ripple current of the inductor L1 (e.g., inductor L1 in the buck topology shown in FIG. 16, inductor L1 in the boost topology shown in FIG. 18, inductor L1 in the buck-boost topology shown in FIG. 20, and inductor L1 in the transformer topology shown in FIG. 22). Similarly, each of FIGS. 16, 18, 20, and 22 also show the inductors L2 and L3, which are connected so as to operate in the manner described above. In some embodiments, the inductor L3 may also be employed to reduce the overlap time between S3 and one or more of switches S1 and S2. Furthermore, inductor L3 can also facilitate control over the DC voltage, which can assist in adjusting one or more Vstep and Icomp, as described herein and elsewhere throughout the disclosure.

In some circumstances, a smaller bulk inductor value for L1 can be utilized (e.g., reduction by ~2x, ~4x, etc.), with the tradeoff being the cost of higher (but acceptable) bowing.

For the sake of brevity, a detailed description of all the connections between the various inductors, diodes, switches, etc., are not provided for the other topologies depicted in FIGS. 18, 20, and 22 because the description of the topology shown in FIG. 16 together with the diagrams of FIGS. 18, 20, and 22 detail the structure and connections of the various components depicted in the other topologies.

As discussed above, each of the four topologies depicted in FIGS. 16, 18, 20, and 22 (e.g., the buck, boost, buck-boost, and transformer topologies) may operate with switch overlaps on either a negative edge or a positive edge, may employ inductor shorting, have high voltage stresses (e.g., at least +/- 3kV), and may utilize high turn off current action (e.g., high turn off current DCM buck action, or high turn off current DCM inverting boost or buck-boost action). In some instances, such as for the switch overlap buck-boost connection on the positive edge, the connection to the output may be a critical switching loop. Furthermore, the transformer coupled voltage source on positive edge (FIG. 22) may have the lowest voltage stress (e.g., 2-3 kV) and may require high switching currents to get an adjustable voltage relative to the embodiments of FIGS. 16, 18, and 20. Furthermore, the transformer topology of FIG. 22 may need a high root-mean square (RMS) current from freewheeling time in some implementations.

While not necessary, switch overlap buck and/or transformer coupled resonant inductor topologies may be optimal in some, but not all instances. Typically, the switch overlap buck topology is associated with low currents (but a tradeoff between the switching current/falltime). However, the switch overlap buck typically utilizes switching loops that are quick and efficient to minimize. On the other hand, the transformer coupled resonant inductor is associated with low voltage stress. But, similar to the switch overlap buck, the switching loops in the transformer coupled resonant inductor may also be relatively easy to minimize. However, it should be noted that the boost and/or buck-boost topologies may be more efficient, effective, robust, etc., in certain use cases, where implementation of switch overlap buck or transformer coupled resonant inductor may not be feasible.

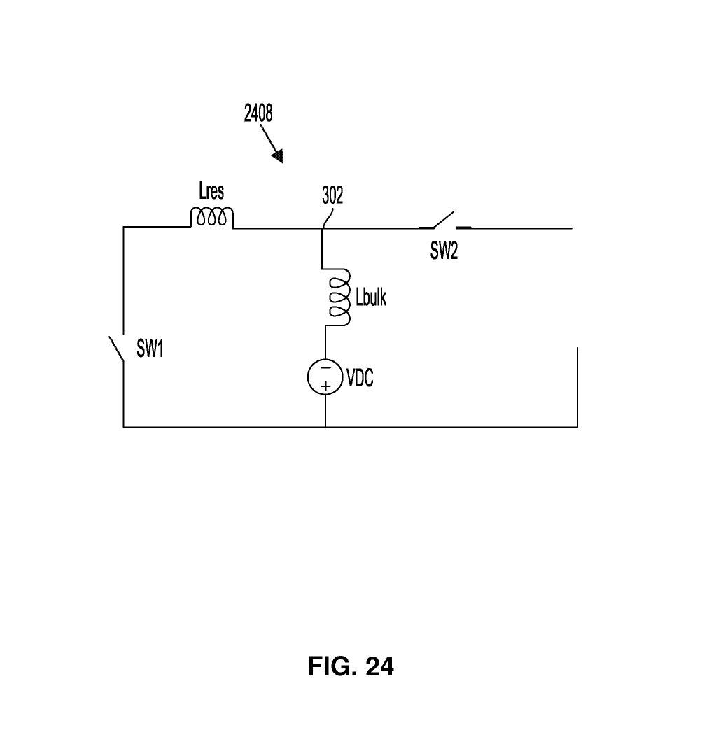

FIG. 24 shows an example of a bias supply 2408. As shown, the bias supply 2408 comprises a switch SW1 coupled to an inductor, Lres, and inductor Lres may be coupled at a node 312 to an inductor Lbulk and a switch SW2. The switch SW1 may also be coupled to a positive node of a power supply VDC, which in this embodiment may be an adjustable DC power supply and may provide a range of voltages. In other examples, power supply VDC may be a fixed voltage power supply.

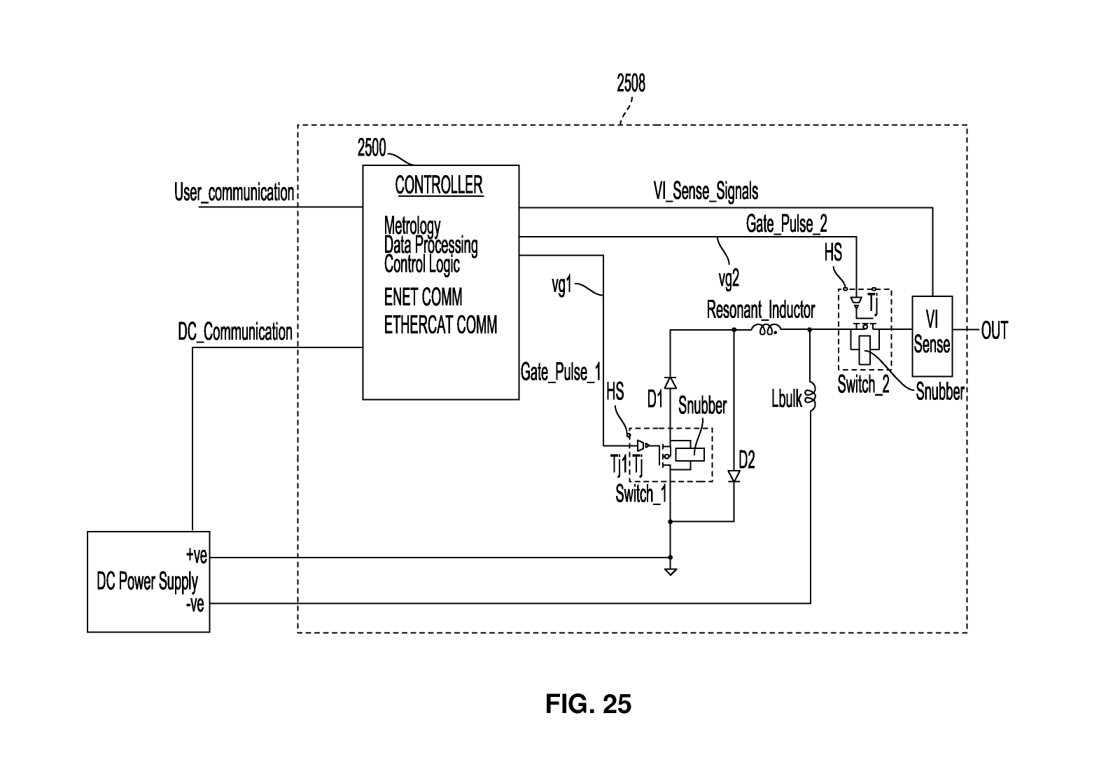

FIG. 25 shows an implementation of a bias supply 2508 and may include components of bias supply 2408. Bias supply 2508 may comprise a switch Switch_1 coupled to an anode of a diode D1 and the cathode of the diode D1 may be coupled to an inductor Resonant_Inductor. And inductor Resonant_Inductor may be coupled to both an inductor Lbulk and a switch Switch_2. The switch Switch_2 may be coupled to a sensor VI Sense at a node that may function as an output to the bias supply 300B, and the sensor VI Sense may be coupled to a controller CONTROLLER. In further embodiments, the second diode may be realized as a body diode associated with the first switch, when the first switch is implemented as a MOSFET. In other embodiments, such as depicted, the second diode may be implemented as a separate component. The switches are depicted in FIG. 25 as MOSFETs, but in variations may be realized as any of a variety of possible switches, such as relays, IGBTs, and the like. While the first and second switches are each depicted as including a snubber network, such a network is not required, and should not be viewed as limiting.

The controller may comprise metrology, data processing, and control logic. As shown, the controller is coupled to a gate of the first switch and a gate of the second switch so that the controller may provide gate signals to the switches. The controller is also coupled by a communication line to the DC power supply to enable the controller to adjust a voltage of the DC power supply. The controller may control the gate drive signals to each of the switches and/or may control the DC voltage of the power supply based upon feedback from the sensor. As one of ordinary skill in the art will appreciate, the sensor may be realized by a variety of sensors that provide information indicative of voltage and/or current at the output of the bias supply. For example, and without limitation, the sensor may be realized by a VI sensor, a directional coupler or by separate voltage and current sensors.

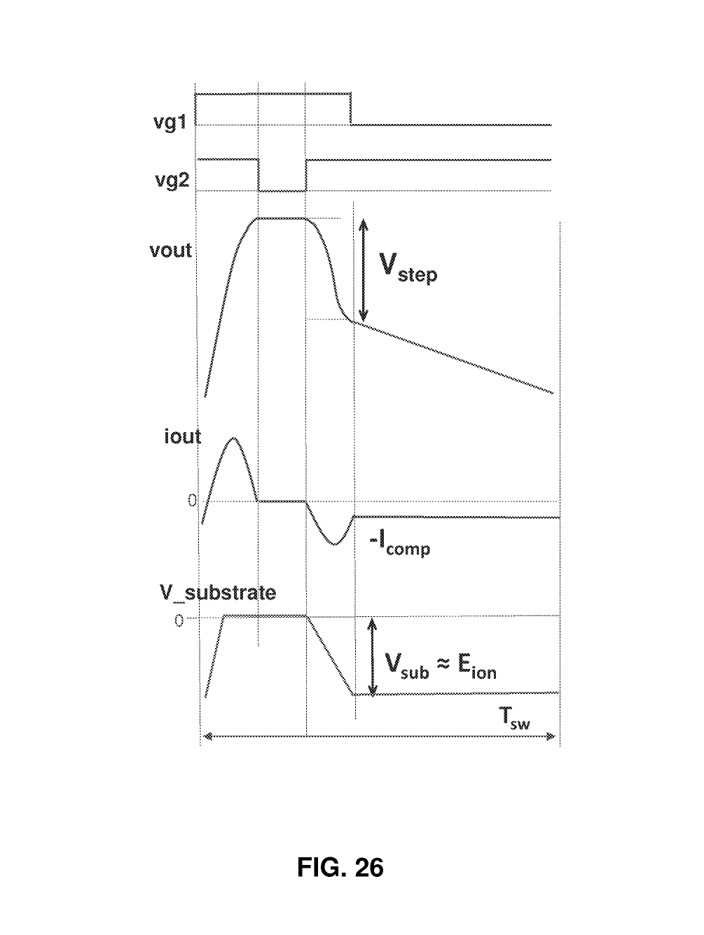

Referring next to FIG. 26, shown is a timing diagram that depicts the timing of a first gate drive signal vg1 that is provided to the first switch and a second gate drive signal vg2 that is provided to the second switch of the bias supplies 2408, 2508. As one of ordinary skill in the art will appreciate, the gate drive signals correspond to positions of the first and second switches so that a high signal level indicates that the switch is closed and a low signal level indicates that the switch is open. For example, as depicted in FIG. 26, both the first switch and the second switch are initially closed (e.g., both signals are high). Also shown is a voltage waveform (vout) produced by the bias supply 2408, 2508 in response to the depicted gate drive signals. In addition, the output current (iout) of the bias supply 300A and the bias supply 300B is shown. Also depicted is a voltage at a surface of a substrate (V_substrate), which may be the sheath voltage between a plasma within a plasma chamber and the surface of the substrate.

As shown, when both switches are closed, the voltage of the voltage waveform changes until the output voltage reaches a peak voltage and then the second switch is opened and the voltage of the voltage waveform remains at the peak voltage until the second switch is again closed while the first switch is also closed, and at this point in time, the voltage waveform begins to change to produce the depicted voltage step. When the first switch is opened and the second switch is closed, the ramped voltage occurs until both the first switch and the second switch are closed at the start of a new cycle of the voltage waveform. In the example output voltage waveform depicted in FIG. 26, the peak voltage is shown as remaining substantially constant or having little or no droop or slope. In other examples, the peak voltage may experience droop, such as depicted in FIG. 1B.

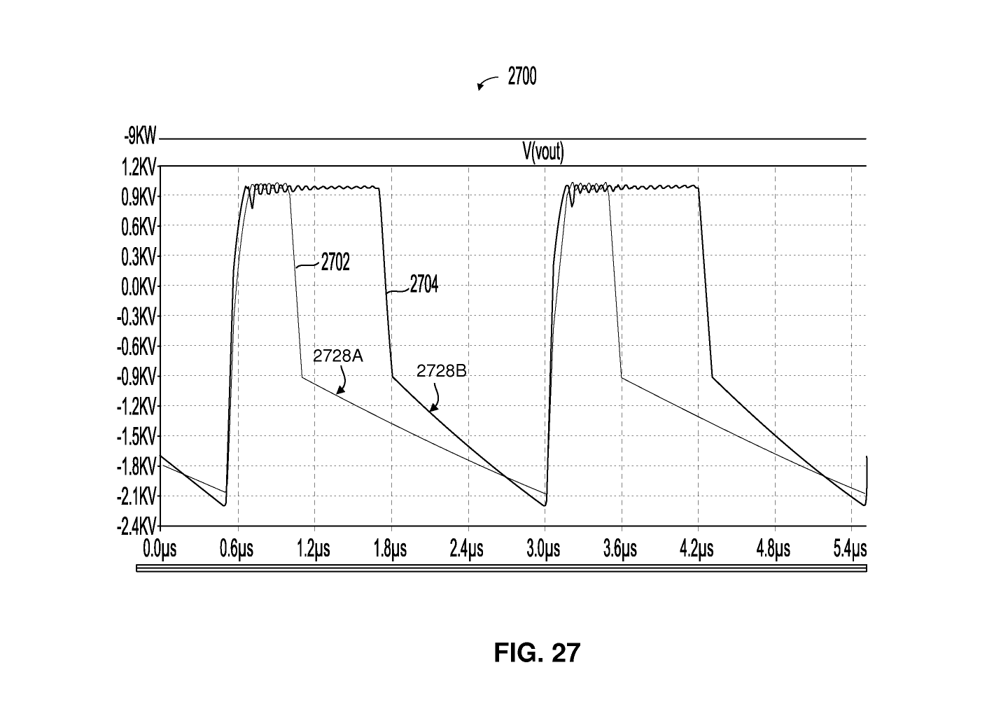

Referring to FIG. 27, shown are two simulated voltage waveforms that may be produced at the output of either the first bias supply 1408 or the second bias supply 1508. As shown, the duty cycle of the voltage waveform may be changed, and in addition, once a peak voltage is reached, the peak voltage in each of the simulated voltage waveforms may be maintained, without a voltage droop, until the voltage step begins. In the example depicted, a waveform 2704 has a larger duty cycle than the waveform 2702. When the duty cycle is increased, the voltage ramp occurring during the voltage ramp portion of the waveform may change accordingly (e.g., the slope of the voltage ramp may increase). For example, as depicted in FIG. 27, waveform 2704 comprises a ramped voltage 2728B that has a greater negative slope than the ramped voltage 2728A of the waveform 2702. Generally, the slope of the voltage ramp may increase or decrease according to the duty cycle, but this behavior is not required. In other examples, the slope of the voltage ramp may remain unchanged, regardless of the duty cycle of the pulse. Consequently, at the end of the ramped voltage portion 128 of voltage waveform 100B, the voltage level of the output voltage waveform at the end (e.g., at the third negative voltage 130) of the ramped portion may vary when the duty cycle is varied.

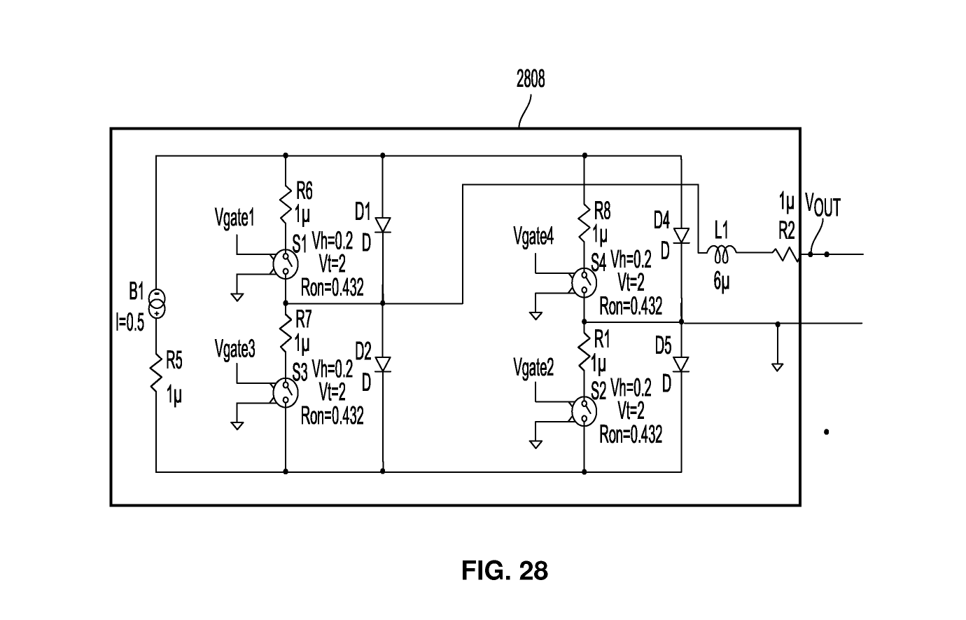

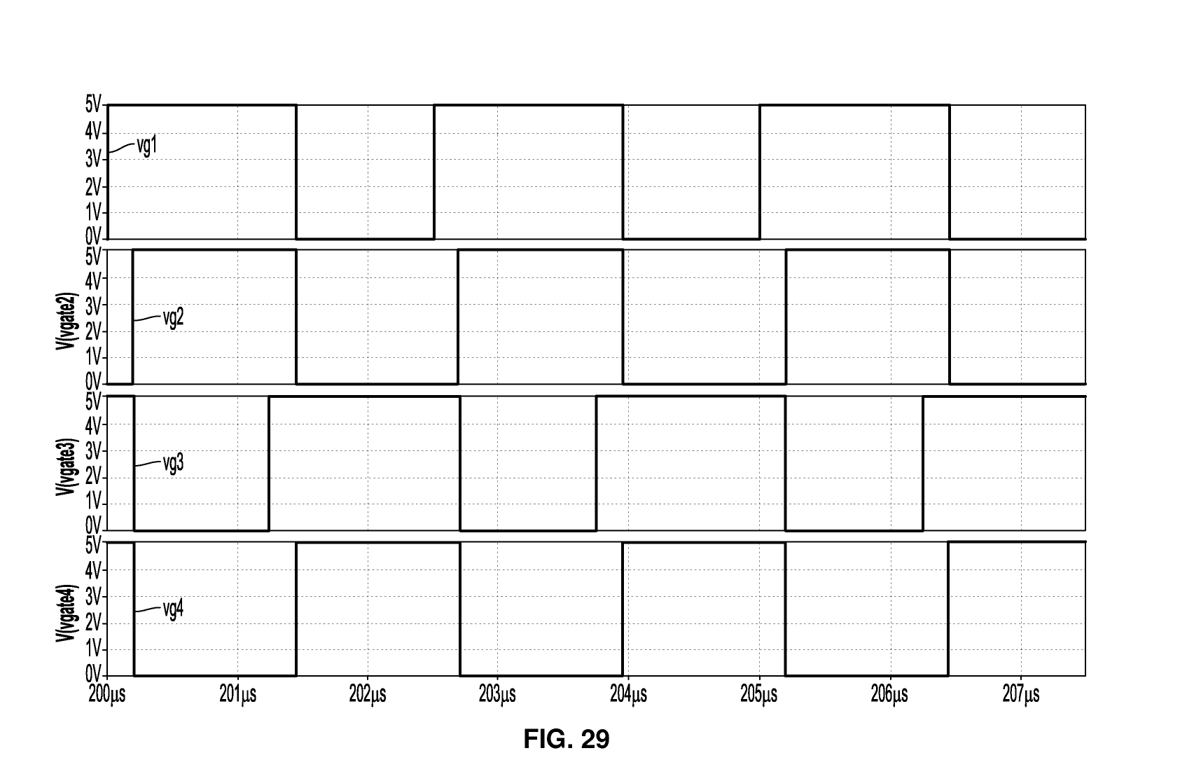

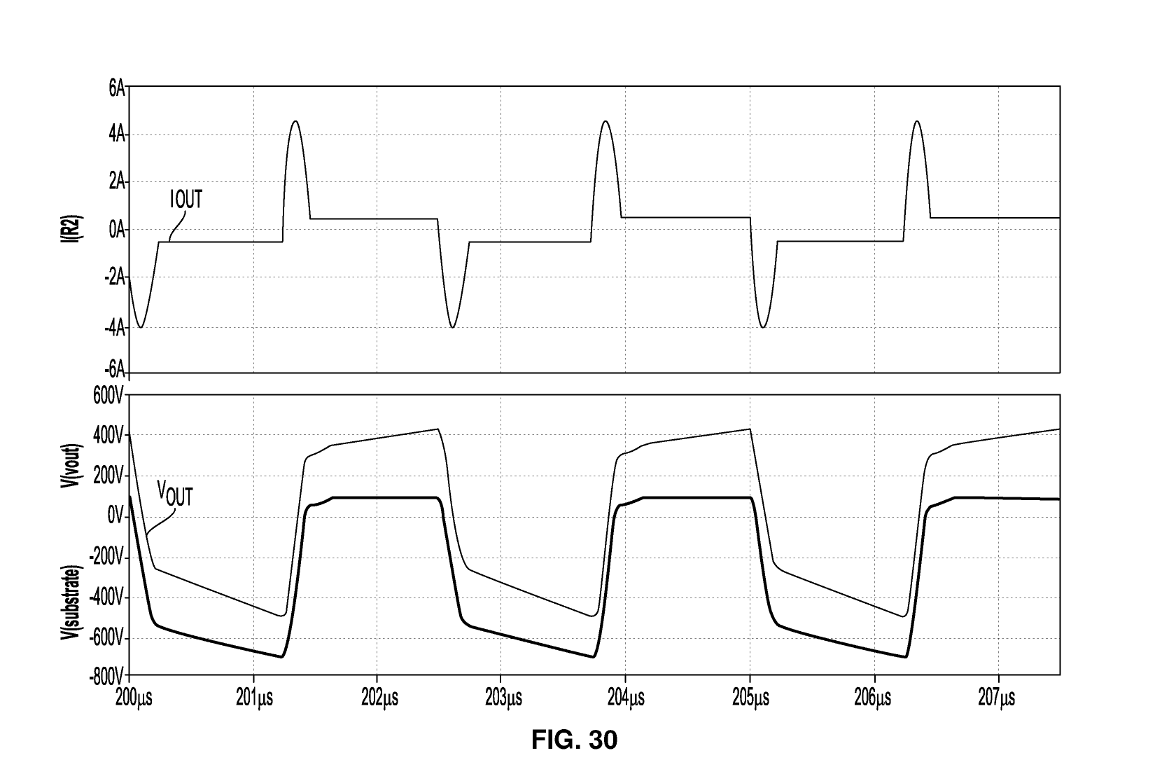

Referring to FIG. 28, shown is another example bias supply 2808 that comprises another topology. As shown, the bias supply 2808 comprises a first switch S1, a second switch S2, a third switch S3, and a fourth switch S4 arranged in a full bridge configuration. And FIG. 29 is a timing diagram for gate drive signals of FIG. 28 corresponding to the switch states for the first switch S1, second switch S2, third switch S3, and fourth switch S4. FIG. 30 depicts a current waveform Iout and a voltage waveform Vout that may be produced by the bias supply 2808. As one of ordinary skill in the art will appreciate in view of this disclosure, the timing for the switch closures may be adjusted to adjust the duty cycle for the waveform. And it is also noted that the output voltage waveform is produced without a voltage droop.

It should be recognized that each of the switches depicted herein generally represents one or more switches that are capable of closing and opening to connect and disconnect, respectively, a current pathway. For example, a single depicted switch may be realized by a plurality of switches arranged in series (for enhanced voltage capability), may be realized by a plurality of switches arranged is parallel (for enhanced current capability), or the switch may be comprised of a plurality of switches arranged in a series-parallel combination (for enhanced voltage and or current capability). In these variations, one of ordinary skill in the art will recognize that each switch that is used to realize the switch may be synchronously driven by a corresponding drive signal.

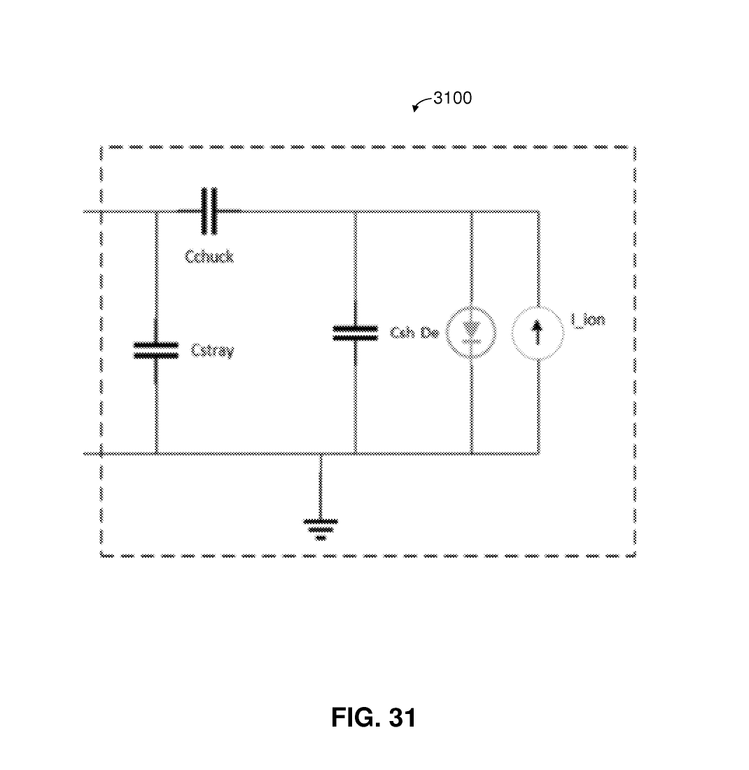

Referring to FIG. 31, shown is a model of a load 3100, which may be a plasma load. But it should be recognized that this load 3100 is only an example and that the load 3100 is not part of the bias supplies disclosed herein. As an example, load 3100 may represent the plasma load of the plasma processing chamber 101 (shown in FIG. 1).

The information and signals disclosed herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The control logic and various illustrative logical blocks, modules, circuits, and algorithm steps described herein may be implemented as electronic hardware, computer software, or combinations of both. To clearly illustrate this interchangeability of hardware and software, various illustrative logic, components, blocks, modules, circuits, and steps have been described above generally in terms of their functionality. Whether such logic and functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC.

Many embodiments and methods described herein may be realized using a processor in connection with processor executable instructions and a field programmable gate array (programmed by hardware description language instructions). The nonvolatile memory may be encoded with instructions that are executable by a processor and/or are readable by a field programmable gate array, e.g., to program the field programmable gate array. In some embodiments, the FPGA is used for high-speed processing and control, including switching control, measurement, pulsing, and multi-level operation while a processor is utilized for other lower-speed processing.

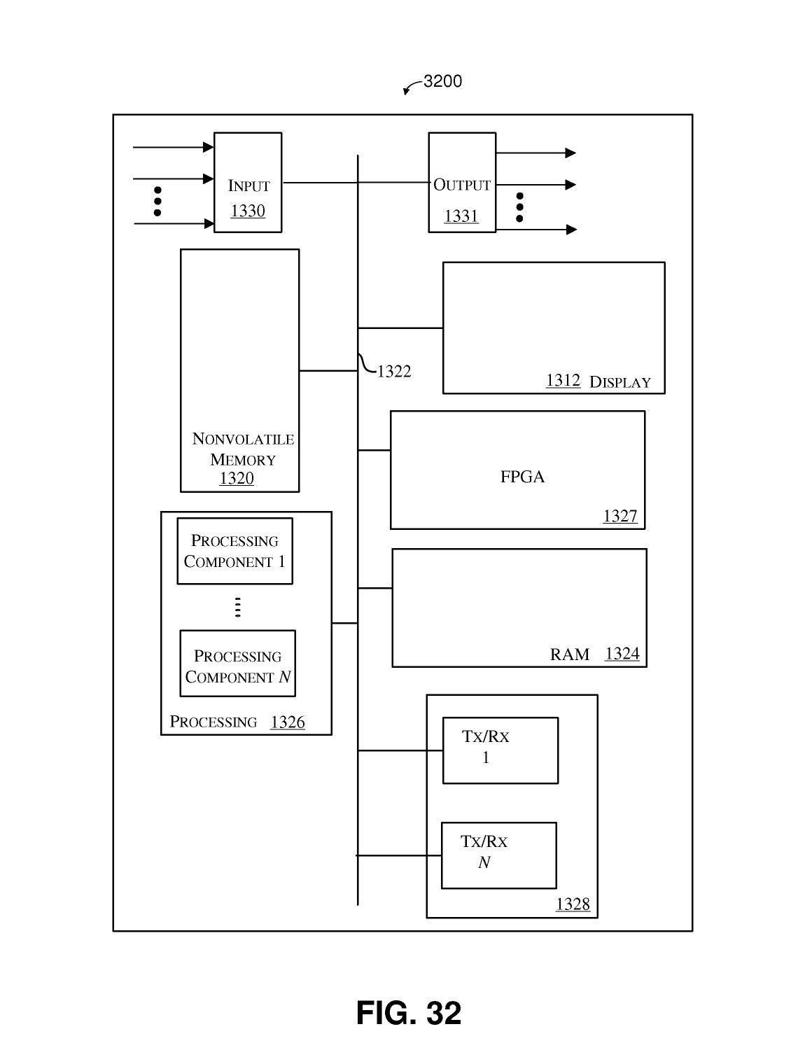

Referring to FIG. 32 for example, shown is a block diagram depicting physical components of a controller 3200 that may be utilized to realize, at least in part, the control logic 228, controller 200, logic associated with the distribution board 215, signal monitor 284, and controller 512 to control aspects disclosed herein.

As shown, in this embodiment a display 1312 and nonvolatile memory 1320 are coupled to a bus 1322 that is also coupled to random access memory (“RAM”) 1324, a processing portion (which includes N processing components) 1326, a field programmable gate array (FPGA) 1327, and a transceiver component 1328 that includes N transceivers. Although the components depicted in FIG. 6 represent physical components, FIG. 32 is not intended to be a detailed hardware diagram; thus, many of the components depicted in FIG. 32 may be realized by common constructs or distributed among additional physical components. Moreover, it is contemplated that other existing and yet-to-be developed physical components and architectures may be utilized to implement the functional components described with reference to FIG. 32.

This display 1312 generally operates to provide a user interface for a user, and in several implementations, the display is realized by a touchscreen display. In general, the nonvolatile memory 1320 is non-transitory memory that functions to store (e.g., persistently store) data and processor-executable code (including executable code that is associated with effectuating the methods described herein). In some embodiments for example, the nonvolatile memory 1320 includes bootloader code, operating system code, file system code, and non-transitory processor-executable code to facilitate the execution of methods for pulse-mode control of the bias supply 208 described herein. The nonvolatile memory 1320 may be encoded with instructions that are executable by a processor and/or are readable by a field programmable gate array, e.g., to program the field programmable gate array wherein the instructions (when executed by the processing portion 1326 or when effectuated by the FPGA 1327) cause the bias supply 208 to carry out the logic and methods disclosed herein. Those of ordinary skill in the art will also appreciate that the FPGA 1327 may also comprise a non-transitory medium that is integrated with the FPGA.

In many implementations, the nonvolatile memory 1320 is realized by flash memory (e.g., NAND or ONENAND memory), but it is contemplated that other memory types may be utilized as well. Although it may be possible to execute the code from the nonvolatile memory 1320, the executable code in the nonvolatile memory is typically loaded into RAM 1324 and executed by one or more of the N processing components in the processing portion 1326.

The N processing components in connection with RAM 1324 generally operate to execute the instructions stored in nonvolatile memory 1320 to enable execution of the logic, algorithms and functions disclosed herein. It should be recognized that several algorithms are disclosed herein are disclosed in terms of text and timing diagrams. Processor-executable code to effectuate methods described herein may be persistently stored in nonvolatile memory 1320 and executed by the N processing components in connection with RAM 1324. As one of ordinarily skill in the art will appreciate, the processing portion 1326 may include a video processor, digital signal processor (DSP), micro-controller, graphics processing unit (GPU), or other hardware processing components or combinations of hardware and software processing components (e.g., an FPGA or an FPGA including digital logic processing portions).

In addition, or in the alternative, non-transitory FPGA-configuration- instructions may be persistently stored in nonvolatile memory 1320 and accessed (e.g., during boot up) to configure a field programmable gate array (FPGA) to implement the algorithms disclosed herein.

The input component 1330 may receive power related signals (e.g., indicative of output current, Iout, and voltage, Vout) obtained (e.g., by current transducers, VI sensors, and/or voltage sensors). The input component 1330 may also receive settings such as for one or more of the first negative voltage 121, rising edge 120, peak voltage 122, beginning voltage 134, falling edge 124, voltage step 132, second negative voltage 126, and ramped voltage 128. The output component 1331 may provide analog and/or digital signals to provide information or to provide control signals. As examples without limitation, the output component 1331 may provide the gate drive signals (e.g., one or more of vg1, vg2, vg3, vg4, etc.)) and signals to control voltage levels of the first DC module 242, second DC module 243, second power supply 304, first power supply 326, first power supply 724, second power supply 711, and power supply, V1.

Although not required, in some implementations the FPGA 1327 may sample the power-related signals and provide the digital representations of output current, Iout, and voltage Vₒᵤₜ. But the FPGA 1327 may also be used to implement these functions. In addition, the input component 1330 may receive phase information and/or a synchronization signal between bias supplies 108 and source generator 112 that are indicative of one or more aspects of an environment within a plasma processing chamber 101 and/or synchronized control between a source generator and the bias supply. Additional signals received at the input component 1330 may include, for example, synchronization signals, power control signals to the various generators and power supply units, or control signals from a user interface. Those of ordinary skill in the art will readily appreciate that any of a variety of types of sensors such as, without limitation, directional couplers and voltage-current (VI) sensors, may be used to sample power parameters, such as voltage and current, and that the signals indicative of the power parameters may be generated in the analog domain and converted to the digital domain.

The depicted transceiver component 1328 includes N transceiver chains, which may be used for communicating with external devices via wireless or wireline networks. Each of the N transceiver chains may represent a transceiver associated with a particular communication scheme (e.g., WiFi, Ethernet, Ethercat, universal serial bus, Profibus, etc.).

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

As used herein, the recitation of “at least one of A, B and C” or “at least one of A, B or C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. An apparatus comprising:
a first node;
a switch section configured to produce a voltage waveform at the first node while the first node is coupled to a load, the voltage waveform comprising a rising edge that reaches a peak and a falling edge that falls from the peak; and
a controller configured to operate the switch section so the switch section neither provides current to first node nor receives current from the first node at a time between the rising edge and the falling edge.

2. The apparatus of claim 1, wherein current is provided to the first node during the rising edge.

3. The apparatus of claim 2, wherein current is received from the first node during the falling edge.

4. The apparatus of claim 1, comprising a second node wherein the switch section produces the voltage waveform at the first node relative to ground.

5. The apparatus of claim 1, wherein the rising edge starts from a first negative voltage and the falling edge reaches a second negative voltage that is followed by a voltage ramp between the second negative voltage and a third negative voltage.

6. The apparatus of claim 5, wherein the second negative voltage and the third negative voltage are the same negative voltage.

7. The apparatus of claim 5 wherein the second negative voltage and the third negative voltage are different negative voltages.

8. The apparatus of claim 1, comprising a power module configured to provide power to the switch section.

9. The apparatus of claim 8, wherein the power module comprises two power supplies.

10. A method comprising:
providing a voltage waveform to a processing chamber with a bias supply, the voltage waveform comprising a rising edge that reaches a peak and a falling edge that falls from the peak,
providing current to the processing chamber during the rising edge;
receiving current from the processing chamber during the falling edge; and
disconnecting current between the bias supply and the processing chamber during the peak.

11. The method of claim 10, wherein the falling edge is followed by a voltage ramp.

12. The method of claim 11, wherein the voltage waveform is an asymmetrical waveform.

13. The method of claim 10, comprising circulating current within the bias supply during the peak.

14. An apparatus comprising:
a first node;
a first switch that couples the first node to a second node, and responsive to the first switch being closed, a rising edge of a voltage waveform is produced at the first node until a voltage peak is reached;
a second switch that couples a third node to the first node, and when the second switch being closed, a voltage step is produced at the first node; and
a third switch configured to close to circulate current within the apparatus during the voltage peak while the first switch and the second switch are open.

15. The apparatus of claim 14, wherein the first switch is in a current path comprising a diode and an inductor.

16. The apparatus of claim 15, wherein the second switch is in a current path comprising a second diode and a second inductor.

17. The apparatus of claim 14, comprising:
a first inductor and a first diode in series with the first switch;
a second inductor in series with the second switch and a second diode when the second switch is closed and the third switch is open; and
a third inductor in series with the second inductor, the second switch, and a third diode when the second switch is closed and the third switch is open.

18. The apparatus of claim 17, wherein the current circulates in a loop that comprises the third switch, the third inductor and a fourth diode when the third switch is closed.

19. The apparatus of claim 18, comprising:
a first direct current power supply coupled between the third inductor and a ground node that is configured to couple to a ground voltage, wherein a negative terminal of the first power supply is coupled to the third inductor and a positive terminal of the first power supply is coupled to the ground node.

20. The apparatus of claim 19, comprising:
a second direct current power supply coupled between the second diode and the ground node.
